(19) United States
(12) Patent Application Publication
(10) Pub. No.: US 2008/0282967 A1
(43) Pub. Date: Nov. 20, 2008

(54) Crystal Growth Method and Apparatus

(76) Inventor: Moshe Einav, Kefar Uriyah (IL)

Correspondence Address: MERCHANT & GOULD PC, P.O. BOX 2903, MINNEAPOLIS, MN, 55402-0903, US

(21) Appl. No.: 11/629,423

(22) PCT Filed: Jun. 15, 2005
(86) PCT No.: PCT/IL05/00630

§ 371 Date: May 28, 2008

Related U.S. Application Data
(60) Provisional application No. 60/579,684, filed on Jun. 16, 2004.

(51) Int. Cl. C30B 31/00; C30B 11/00

(52) U.S. Cl. 117/1; 117/206

(57) ABSTRACT

A method for forming a uniformly oriented crystalline sheet, wherein a plurality of crystallites are introduced into a liquid. At least a portion of the crystallites float on the surface of the liquid, and are induced to self-orientate until they are uniformly oriented in a compact mosaic configuration, while their sintering is prevented. A uniformly oriented crystalline sheet is formed from the compact mosaic configuration, for example, by sintering the crystallites. An apparatus for forming a crystalline sheet includes a container containing a liquid, wherein a plurality of crystallites are introduced and at least a portion thereof float on the surface of the liquid without sintering. The apparatus also includes a flow unit for inducing a flow of the liquid which moves the floating crystallites, and self-orientation means for allowing self-orientation of the floating crystallites, without sintering, until the floating crystallites are uniformly oriented in a compact mosaic configuration, ready for forming a uniformly oriented crystalline sheet, for example, by sintering the crystallites.

### FIELD OF THE DISCLOSED TECHNIQUE

The disclosed technique relates to crystal growth in general, and to improved methods and systems for producing sheets of crystals in particular.

### BACKGROUND OF THE DISCLOSED TECHNIQUE

A crystal is a solid having a regularly repeating, characteristic internal structure, known as a lattice, and sometimes also has its external plane faces symmetrically arranged. In crystals, the particles (i.e., atoms, ions or molecules) forming the crystal possess a three-dimensional repeating arrangement that extends in all three spatial directions. Crystals can also be referred to as single crystals, since they possess a particular and unique repeating pattern and arrangement of particles. A crystallite is a small crystal and can be defined as having a surface area up to the order of several microns squared (μm²). A polycrystal is a solid that lacks a regular repeating, characteristic internal structure. In general, polycrystals may sometimes be formed from an aggregate of grains, i.e., single crystals, crystallites, or groups of particles, each possessing a repeating arrangement over a small distance, for example, up to a few micrometers. The contact zones between adjacent grains are referred to as grain boundaries in the art. In general, single crystals may be produced in different shapes and forms, such as bulk crystals, wafers, sheets and thin films. Crystalline sheets may be considered to be substantially two-dimensional, since their height may be very small compared to their width and length. In comparison, bulk crystals are considered as being substantially three-dimensional.

Crystals normally grow epitaxially by the addition of individual particles, one at a time, to a solid substrate composed of the same particles. As such, layer upon layer of the individual particles add to the solid which eventually, over time, constitute the grown crystal. One method of crystal growth is known as homo-epitaxial crystal growth, in which a crystalline platform substrate of a substance is used to grow crystals of the same substance. One by one, particles of the substance are introduced to the substrate and initially form bonds with particles on the surface of the substrate. Over time a grown crystal is formed. Since the substrate and the grown crystal are of the same substance, the grown crystal will acquire the lattice structure of the substrate. If the homo-epitaxial substrate has crystal defects therein, depending on the type of defects, the grown crystal may inherent these defects during the growth process.

Another method of crystal growth is known as hetero-epitaxial crystal growth, in which a crystalline platform substrate of a substance is used for the growth of a lattice structure of a different substance. The substrate and the grown crystal should have similar lattice structures, so that the grown crystal may acquire the lattice structure of the substrate. Hetero-epitaxial crystal growth is commonly used for producing thin film crystals. Since the substrate and the grown crystal are not of the exact same substance, differences in lattice structure and in the coefficient of thermal expansion of the substrate and the grown crystal may exist, causing various crystal defects to appear in the grown crystal. For essentially two dimensional crystals such as thin film crystals, the quality of a crystal can be measured according to the density of crystal defects, or the density of a particular type of crystal defect, per centimeter squared (defects/cm²). Homo-epitaxially grown crystals usually have a smaller defect density than hetero-epitaxially grown crystals since the substrate and grown crystal are of the same substance in homo-epitaxial crystal growth. As such, homo-epitaxial crystal growth is used unless a substrate of the same substance as the grown crystal cannot be found. In such a case, hetero-epitaxial growth is used.

Crystals are often used for various industrial applications, such as microelectronics, for which crystalline imperfections (i.e., crystal defects) are undesirable. A high density of dislocation defects renders grown crystals not useful for microelectronics and related applications. In such applications, for two-dimensional crystals (which are commonly required by the industry) the maximum dislocation defect density for proper operation is 10³ dislocation defects/cm². In particular, crystals for use in industrial applications (i.e., crystals with a dislocation defect density less than 10³ defects/cm²) can be grown in sizes of up to approximately 300 mm. At such sizes, devices made of such crystals can be fabricated on the order of millimeters and centimeters. For devices, such as large solid state monitors and large fields of photovoltaic cells, large single crystals are needed. Therefore, crystals used in such industrial applications should desirably be of large dimension and of high quality, such that they may be applied to large-scale components and devices.

Examples of crystal defects, at the particle level, can include vacancies, impurities and interstitial atoms (point defects), dislocations (linear defects), and grain boundaries and stacking faults (planar defects). In particular, dislocations occur when atoms are absent from their original positions in the lattice of a crystal, such that a portion of the lattice exhibits a deficit in atoms, while the rest of the lattice contains the proper number of atoms for a given lattice structure. Dislocations can be caused by various reasons. For example, in hetero-epitaxial growth, when a substrate of a particular substance imposes a particular lattice structure on particles of a different substance, misfit dislocations may occur. Also, when crystals are grown at high temperatures, and subsequently relaxed by a process of cooling, because the process of cooling isn't a homogenous one (due to the geometry of the grown crystals and the temperature gradient within the crystals), thermal dislocations may occur. In general, as the grown crystal increases in size, and as the growth temperature of crystals increases, the number of dislocations increases. Crystal defects may alter the physical and chemical properties of the crystal, thereby damaging advantageous properties thereof, such as electrical conductivity, optical properties and the like, for example, by increasing leakage currents in diodes, serving as a non-radiative recombination centers, serving as a dopant diffusion paths or acting as a source of noise in photodetectors. Regarding hetero-epitaxial crystal growth, a large difference in the coefficient of thermal expansion (CTE) between the substrate and the grown crystal may cause mechanical stress thereon, such that dislocations may appear in the grown crystal, which may further affect the properties thereof and render the grown crystal not useful for industrial applications.

Homo-epitaxial, as well as hetero-epitaxial crystal growth may be used to produce crystals of any kind of substance having a crystalline structure. In particular, such methods may be applied to producing crystals of nitrides of group-III metals of the periodic table. Group-III metals of the periodic table (i.e., aluminum, gallium and indium) can form nitrides, i.e., aluminum nitride (AlN), gallium nitride (GaN) and indium nitride (InN). Group-III metal nitrides are semiconductors having various energy gaps (between two adjacent allowable bands), e.g., a narrow gap of 0.7 eV for InN, an intermediate gap of 3.4 eV for GaN, and a wide gap of 6.2 eV for AlN. Solid group-III metal nitrides have an ordered crystalline structure, giving them advantageous chemical and physical properties, such that electronic devices made from group-III metal nitrides can operate at conditions of high temperature, high power and high frequency. Furthermore, group-III metal nitrides are considered relatively chemically inert.

Electronic devices made from group-III metal nitrides may emit or absorb electromagnetic radiation having wavelengths ranging from the UV region to the IR region of the spectrum, which is particularly relevant for constructing light emitting diodes (LED), solid-state lights and the like. Other examples of applications of group-III metal nitride crystals are solid-state full color displays, optical storage devices, signal amplification devices, photovoltaic cells, under-water communication devices, space communication devices and the like. Furthermore, group-III metal nitrides may be used for other devices exhibiting solid state physical effects such as high semi-conducting electron mobility and saturation, opto-electricity, photo-luminescence, electro-luminescence, electron-emission, piezo-electricity, piezo-optics, diluted magnetism and the like.

Epitaxial crystal growth of group-III metal nitrides may be performed using various materials as substrates. These substrates should be of high lattice quality (i.e., low defect density), in order to achieve high quality crystal growth. To be used in various technological applications, the group-III metal nitride crystals may be in the form of a free-standing wafer or a thin film, attached to an arbitrary platform of conducting, semi-conducting, or dielectric nature. For other uses, group-III metal nitrides may be in the form of a free-standing bulk crystal. For industrial applications, group-III metal nitride crystals of large size (i.e., substantially 25 mm or larger) are required. However, crystals of large size, having a low defect density, are difficult to manufacture.

Group-III metal nitride crystals are not found naturally and are commonly artificially produced as thin films on a crystalline substrate, by methods known in the art. Among the group-III metal nitrides, gallium nitride can be produced using hetero-epitaxy, wherein the substrate used as a hetero-epitaxial template can be, for example, a single-crystalline wafer of sapphire (Al₂O₃), on which a layer of GaN is deposited. Alternatively, a silicon carbide (SiC) wafer may be used as a substrate. However, due to the difference in lattice structure between the substrate and the GaN layer, various crystal defects may appear in the GaN crystal. Other known methods for growing group-III metal nitride crystals use a metallic melt, typically of the group-III metal. Nitrogen is supplied to the melt and chemically reacts with the group-III metal in the melt, thereby enabling crystal growth. Such methods usually require special pressure and temperature conditions for allowing the growth of the crystals from the liquid. Furthermore, these growth methods are often expensive, and the crystal dimensions achieved, as well as the quantity of crystals produced, are typically small for industrial applications.

PCT Publication WO 98/19964, to Angus et al., entitled “Method for the Synthesis of Group III Nitride Crystals,” is directed to a method for producing group-III nitride crystals from a liquid. The method is directed, in particular, to producing gallium nitride crystals. In one example, liquid gallium is held in a boron nitride crucible. The pressure inside the reaction chamber is reduced and the liquid is then heated to promote the desorption of trapped gas. An argon beam plasma and a hydrogen plasma are then used to remove impurities from the surface of the liquid gallium. An active nitrogen plasma is then used and the crucible is heated slowly, while pressure inside the crucible is maintained. Once the final temperature of 700° C. is attained, the nitrogen plasma beam is maintained on the surface of the liquid gallium for 12 hours. A supersaturation of the nitrogen is obtained and spontaneous crystallization occurs without cooling. Gallium nitride crystallizes on the surface of the liquid and forms a solid crust of GaN. A temperature gradient is imposed across the liquid surface such that one side of the liquid is held at a higher temperature than the other side. The solid GaN crust dissolves at the high temperature side and nitrogen is transported through the melt to the low temperature side, where the solid GaN recrystallizes. In this manner small crystals of solid GaN can be converted into larger crystals. In one example, a solid GaN polycrystalline dome, about 0.1 mm thick and having a surface area of 70 mm², was obtained. Scanning electron micrographs revealed randomly oriented crystallites of different structures (FIGS. 6 and 7). A transmission electron micrograph of a hexagonal platelet, found within the concave side of a GaN polycrystalline dome, revealed no dislocation defects, although other defects were present.

Li, H., and Sunkara, M., “Self-Oriented Growth of Gallium Nitride Films on Amorphous Substrates,” Proceedings of the 4th Symposium on Non-Stoichiometric III-V Compounds (2002) is directed to a method for growing gallium nitride crystal films from a melt of gallium. Thin films of molten gallium are spread on an amorphous substrate. The gallium films are exposed to nitrogen plasma (i.e., nitrogen ions) and heated to a temperature of 9000-1,000° C. for 1-3 hours at a pressure of 100 mtorr. Gallium nitride crystals nucleate from the molten gallium, and self-orient with respect to each other due to the mobility of the melt. Separate platelets of GaN join together and form a larger GaN film. It is noted that the self-orientation of gallium nitride crystals described in the method of Li and Sunkara is not perfect, and that certain regions of the GaN film obtained contain joined crystals which are misorientated in a common plane with respect to one another. Such misorientations create gaps, or holes, between adjacent crystals, and render that region and layer of the crystal not useful for industrial applications. Other regions of the GaN film obtained contain platelets which are misoriented and are not in a common plane, whereby the platelets point in different directions with respect to one another. It is also noted that the GaN film obtained by the method of Li and Sunkara exhibits grain boundaries, which, between some platelets, is hardly seen due to complete joining of the platelets.

Other methods for growing group-III nitride crystals can be found in U.S. Pat. No. 5,637,531, and U.S. Pat. No. 6,780,239.

### SUMMARY OF THE DISCLOSED TECHNIQUE

It is an object of the disclosed technique to provide a novel method and system for forming a uniformly oriented crystalline sheet. In accordance with the disclosed technique, there is thus provided a method for forming a uniformly oriented crystalline sheet. A plurality of crystallites are introduced into a liquid, wherein at least a portion of the crystallites float on the surface of the liquid. The crystallites are then induced to self-orientate until they are uniformly oriented in a compact mosaic configuration, while their sintering is prevented. A uniformly oriented crystalline sheet is formed from the compact mosaic configuration, for example, by sintering the crystallites. In accordance with the disclosed technique, there is also provided an apparatus for forming the crystalline sheet including a container containing a liquid, wherein a plurality of crystallites are introduced and at least a portion thereof float on the surface of the liquid without sintering. The apparatus also includes a flow unit for inducing a flow of the liquid which moves the floating crystallites, and self-orientation means for allowing self-orientation of the floating crystallites, without sintering, until the floating crystallites are uniformly oriented in a compact mosaic configuration. The floating crystallites are then ready for forming a uniformly oriented crystalline sheet, for example, by sintering the crystallites.

In accordance with an embodiment operative according to the disclosed technique, there is provided a method for forming a crystalline sheet, including introducing a plurality of crystallites in a first location of a liquid, wherein the liquid has inherent chemical and physical properties with respect to the crystallites such that at least a portion of the crystallites are floating crystallites which float on the surface of the liquid. The introduction of the crystallites is carried out while preventing sintering of the floating crystallites in the first location. The method further includes arranging the floating crystallites in a uniformly oriented compact mosaic configuration, while still preventing sintering of the floating crystallites. Arranging includes inducing movement of the floating crystallites from the first location to a second location of the liquid, and allowing self-orientation of the floating crystallites in the second location until the floating crystallites are uniformly oriented in a compact mosaic configuration. The method further includes forming a uniformly oriented crystalline sheet from the compact mosaic configuration.

In accordance with another embodiment constructed and operative according to the disclosed technique, there is also provided an apparatus for forming a crystalline sheet, including a container containing a liquid, wherein a plurality of crystallites are introduced into a first location of the container, and wherein at least a portion of the crystallites are floating crystallites that float on the surface of the liquid without sintering. The apparatus includes also a flow unit for inducing a flow of the liquid which moves the floating crystallites from the first location to a second location of the container, without sintering. The apparatus further includes crystal self-orientation means for allowing self-orientation of the floating crystallites in the second location without sintering, until the floating crystallites are uniformly oriented in a compact mosaic configuration. A uniformly oriented crystalline sheet is formed from the compact mosaic configuration.

In accordance with a further embodiment constructed and operative according to the disclosed technique, there is provided an apparatus for forming a crystalline sheet, the apparatus including a first container containing a liquid, wherein a plurality of crystallites are introduced into the first container, and wherein at least a portion of the crystallites are floating crystallites that float on the surface of the liquid without sintering. The apparatus further includes a second container and inducing means for moving the floating crystallites from the first container to the second container, without sintering of the floating crystallites. The apparatus also includes crystal self-orientation means for allowing self-orientation of the floating crystallites in the second container without sintering, until the floating crystallites are uniformly oriented in a compact mosaic configuration, wherein a uniformly oriented crystalline sheet is formed from the compact mosaic configuration.

### BRIEF DESCRIPTION OF THE DRAWINGS

The disclosed technique will be understood and appreciated more fully from the following detailed description taken in conjunction with the drawings in which:

FIG. 1 is a schematic illustration of a crystalline sheet formation system, constructed and operative in accordance with an embodiment of the disclosed technique;

FIG. 2A is a top view of an embodiment of the container of FIG. 1, constructed and operative in accordance with another embodiment of the disclosed technique;

FIG. 2B is a side view of the container of FIG. 2A;

FIG. 3A is a top view of another embodiment of the container of FIG. 1, constructed and operative in accordance with a further embodiment of the disclosed technique;

FIG. 3B is a side view of the container of FIG. 3A;

FIG. 4A is a top view of a further embodiment of the container of FIG. 1, constructed and operative in accordance with another embodiment of the disclosed technique;

FIG. 4B is a side view of the container of FIG. 4A;

FIG. 5 is an enlarged view of a guiding element used in the container of FIG. 4A, constructed and operative in accordance with a further embodiment of the disclosed technique;

FIG. 6A is a schematic illustration of an embodiment of the flow unit of FIG. 1, constructed and operative in accordance with another embodiment of the disclosed technique;

FIG. 6B is a schematic illustration of another embodiment of the flow unit of FIG. 1, constructed and operative in accordance with a further embodiment of the disclosed technique;

FIG. 7 is a schematic illustration of a group-III metal nitride crystalline sheet formation system, constructed and operative in accordance with another embodiment of the disclosed technique;

FIG. 8 is a schematic illustration of a method for forming a crystalline sheet, operative in accordance with a further embodiment of the disclosed technique;

FIG. 9 is a schematic illustration of a crystalline sheet formation method, operative in accordance with another embodiment of the disclosed technique;

FIG. 10 is a schematic illustration of another crystalline sheet formation method, operative in accordance with a further embodiment of the disclosed technique;

FIG. 11 is a schematic illustration of a group-III metal nitride crystalline sheet formation method, operative in accordance with another embodiment of the disclosed technique;

FIG. 12 is a schematic illustration of another group-III metal nitride crystalline sheet formation method, operative in accordance with a further embodiment of the disclosed technique;

FIG. 13 is a schematic illustration of a further crystalline sheet formation method, operative in accordance with another embodiment of the disclosed technique; and

FIG. 14 is a schematic illustration of another crystalline sheet formation method, operative in accordance with a further embodiment of the disclosed technique.

### DETAILED DESCRIPTION OF THE EMBODIMENTS

The disclosed technique concerns the production of oriented crystalline sheets of large dimensions having a low density of crystalline defects and also having a low density of sheet defects.

When a two-dimensional polycrystal is formed from crystallites (i.e., small crystalline platelets), even though the individual crystallites may be perfect defect-less crystallites, the crystallites can still be considered as oriented or misoriented with respect to one another. The orientation of a polycrystal sheet is an attribute of a crystal sheet describing the spatial relation between the crystallites therein and is not related to other defects therein (i.e., crystal defects). If the crystallites are oriented in a common direction, then the polycrystal sheet can be characterized as oriented. If all the crystallites are not oriented in a common direction, then the polycrystal sheet can be characterized as misoreinted. If all the crystallites in a polycrystal sheet can be uniformly oriented and sintered, then the resultant polycrystal sheet can be considered a crystal sheet without crystal sheet defects (misorientations). In general, mainly in the semiconductor industry, a misoriented polycrystal cannot be used as a substrate for industrial devices. In addition to misorientations, other crystalline sheet defects can include holes, gaps, overlapping platelets, voids between platelets planes and the like.

The disclosed technique overcomes the disadvantages of the prior art by providing a novel crystalline sheet production system and method whereby the introduction stage of individual crystallites is segregated from the crystalline sheet formation stage. By physically separating the various stages of crystalline sheet production, uniformly oriented crystalline sheets of large dimension which have a low defect density and also having a low density of crystalline sheet defects can be grown in a relatively short period, for example at a growth rate that exceeds 5 meters squared per hour. The disclosed technique allows the formation of such an oriented crystalline sheet on the surface of a liquid (i.e., without an epitaxial solid substrate). The disclosed technique also allows the formation of such a crystalline sheet at a relatively low temperature. Epitaxial crystal growth methods known in the art are often performed at relatively high temperatures, causing thermal dislocation defects to appear in the grown crystal layer upon cooling. Thus, by providing a crystalline sheet formation system and method, performed without a substrate and at low temperatures, the disclosed technique allows for the production of crystalline sheets having a low density of thermal dislocations.

The disclosed technique utilizes a process of sintering which takes place between a plurality of individual crystallites. When a plurality of individual crystallites (generally of the same substance) are brought in proximity to one another, and sintering conditions (e.g., higher temperature and depositional conditions) are applied thereon, partial surface melting (or filling of gaps by deposited material) of the crystallites occurs, mainly at the edges of the crystallites. As such, the edges of the crystallites are “welded” together. As the crystallites cool, the bonds at the edges solidify and a polycrystalline structure is formed.

The disclosed technique applies to crystalline sheet formation in general, and is not restricted to a crystalline sheet formation of a particular type of crystal. Therefore, the disclosed technique can be used to produce crystalline sheets under a plurality of conditions (i.e., pressure, temperature and the like). Furthermore, any crystalline sheet formation techniques described herein for a particular type of crystal, for example group-III metal nitride crystallites, are merely described as examples of the applicability of the disclosed technique and in no way limit the applicability of the disclosed technique to the described examples. The terms “crystal,” “crystalline,” “crystallite,” “polycrystal,” as well as other inflections on the word “crystal,” are used herein to refer to any type of organic and non-organic substance that can crystallize. It is noted that the terms “crystal sheet” and “crystalline sheet” are used interchangeably hereinafter to refer to a substantially two-dimensional sheet having a crystalline structure.

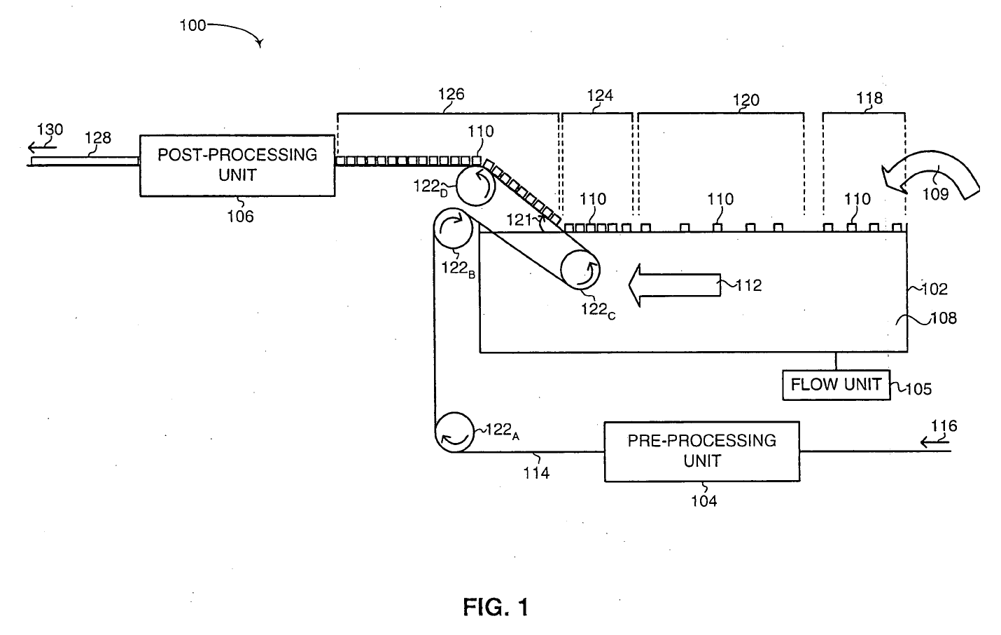

Reference is now made to FIG. 1, which is a schematic illustration of a crystalline sheet formation system, generally referenced 100, constructed and operative in accordance with an embodiment of the disclosed technique. Crystalline sheet formation system 100 includes a container 102, a pre-processing unit 104, a flow unit 105, a post-processing unit 106, a track 114 and rollers 122_{A}, 122_{B}, 122_{C} and 122_{D}. Crystalline sheet formation system 100 can also include elements, for example a vacuum chamber, a pressure chamber, heating means, or cooling means, for altering the pressure and temperature conditions to conditions under which crystalline sheets are formed or crystallites are grown. Container 102 contains a liquid 108. Arrows in rollers 122_{A}, 122_{B}, 122_{C} and 122_{D} indicate the respective direction in which each roller turns. Flow unit 105 is coupled with container 102. Track 114 is coupled with pre-processing unit 104, container 102, rollers 122_{A}, 122_{B}, 122_{C} and 122_{D}, and post-processing unit 106. Track 114 is configured to pass through pre-processing unit 104 and post-processing unit 106. Track 114 is also configured to enter and exit container 102, via rollers 122_{A}, 122_{B}, 122_{C} and 122_{D}. Roller 122_{C} is located within container 102. It is noted that pre-processing unit 104, flow unit 105, post-processing unit 106, track 114 and rollers 122_{A}, 122_{B}, 122_{C} and 122_{D} are optional components in crystalline sheet formation system 100. It is noted that track 114 can refer to a mere conveyer belt, a substrate in the form of a conveyer belt or a substrate placed upon a conveyer belt.

Crystalline sheet formation system 100 includes four sections: a crystal introduction section 118, a crystal transition section 120, a crystalline sheet formation section 124 and a crystal removal section 126. It is noted that crystal transition section 120 is merely described for the sake of clarity, whereas it can be of minimal length or eliminated altogether, as crystal introduction section 118 can be adjacent to crystalline sheet formation section 124 without any spacing there between. It is also noted that crystal removal section 126 is optional.

Sections 118, 120 and 124 of crystalline sheet formation system 100 can each be in the form of a separate container (not shown), and not sections of a single container (as in container 102). For example, section 118 can be a crystal introduction container, section 120 can be a crystal transition container, and section 124 can be a crystalline sheet formation container. If desired, the pressure and temperature conditions in each of the containers can be controlled separately, in order to apply suitable conditions for each of the different stages of crystalline sheet formation system 100. The separate containers can be connected, for example via a duct, through which liquid 108 can flow from one container to another. Alternatively, the separate containers can be completely segregated, and arranged such that liquid 108 is allowed to flow between the separate containers (e.g., due to gravitation, if the crystal introduction container is placed higher than the crystal transition container, and the crystallites are allowed to move from the crystal introduction container to the crystal transition container).

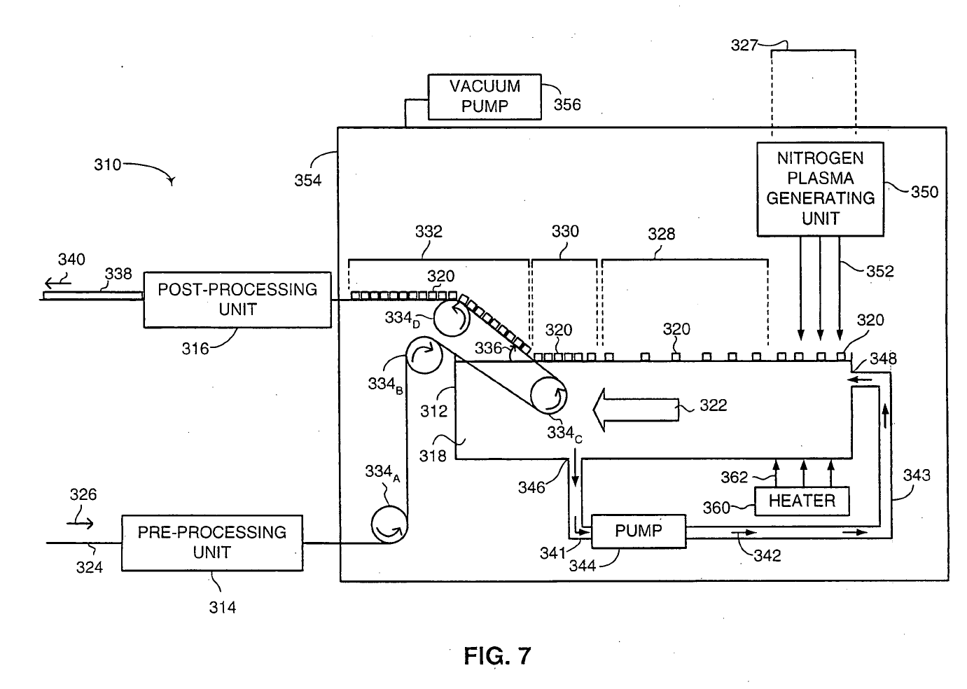

In crystal introduction section 118, a plurality of crystallites 110 (generally of the same substance) is provided to container 102. In an embodiment of the disclosed technique, crystallites 110 can be grown in a portion of container 102 from liquid 108, as described below in reference to FIG. 7, where, as an example, group-III metal nitride crystallites are grown from a group-III metal liquid and a nitrogen plasma generating unit. If crystallites 110 are grown in crystal introduction section 118, then heat can be applied to that section, by a heater (not shown), in order to cause the crystallites to grow if the crystal growth temperature is higher than room temperature.

In another embodiment of the disclosed technique, crystallites 110 can be grown in a different location (other than container 102), and physically provided to a portion of container 102, as depicted by arrow 109. In general, liquid 108 and crystallites 110 should have physical and chemical properties in relation to one another that enable at least a portion of crystallites 110 to float on the surface of liquid 108, for example, through gravitation, surface tension properties, amphiphilic properties and the like. The rate at which crystallites 110 are provided to the surface of liquid 108 should be such that only a single layer of crystallites will be present on the liquid surface in order to avoid over crowdedness of crystallites 110. The temperature in crystal introduction section 118 should generally be lower than the temperature at which sintering of the crystallites occurs, in order to prevent sintering of crystallites 110 in crystal introduction section 118.

According to a further embodiment of the disclosed technique, crystallites 110 are small in size (i.e., on the order of micrometers), and therefore, in general, have a low density of dislocation defects (i.e., lower than 10³ dislocations/cm²). As such, when crystallites 110 are sintered, in crystalline sheet formation section 124, into a continuous crystalline sheet, the formed sheet will also have a low density of dislocations. Thus, by introducing (either growing or providing) small crystallites to crystal introduction section 118, the quality of the formed crystalline sheet is improved, and the dislocation defect density thereof is significantly reduced, rendering the formed crystalline sheet suitable for industrial use.

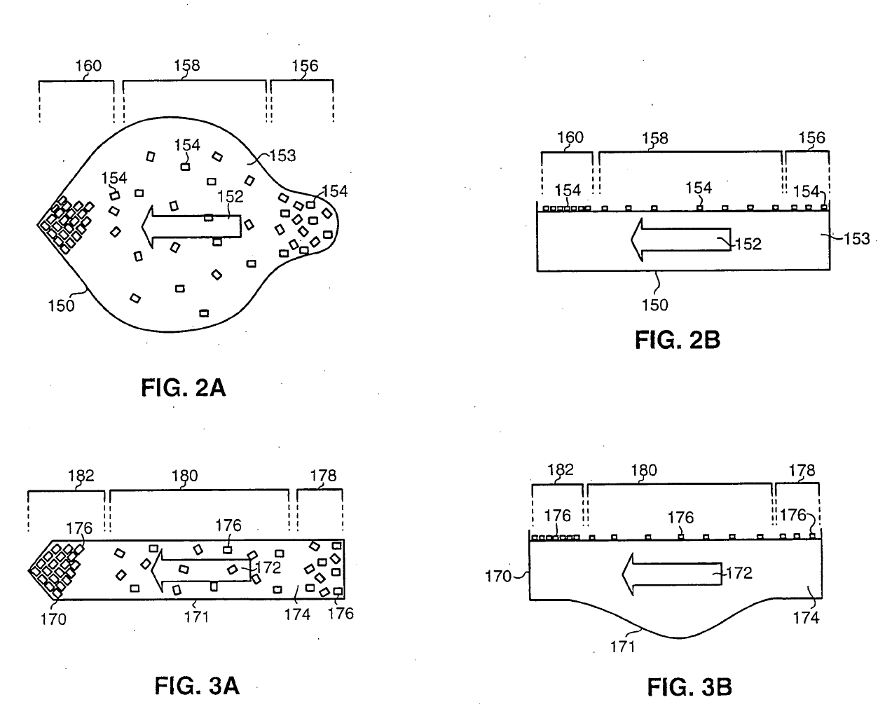

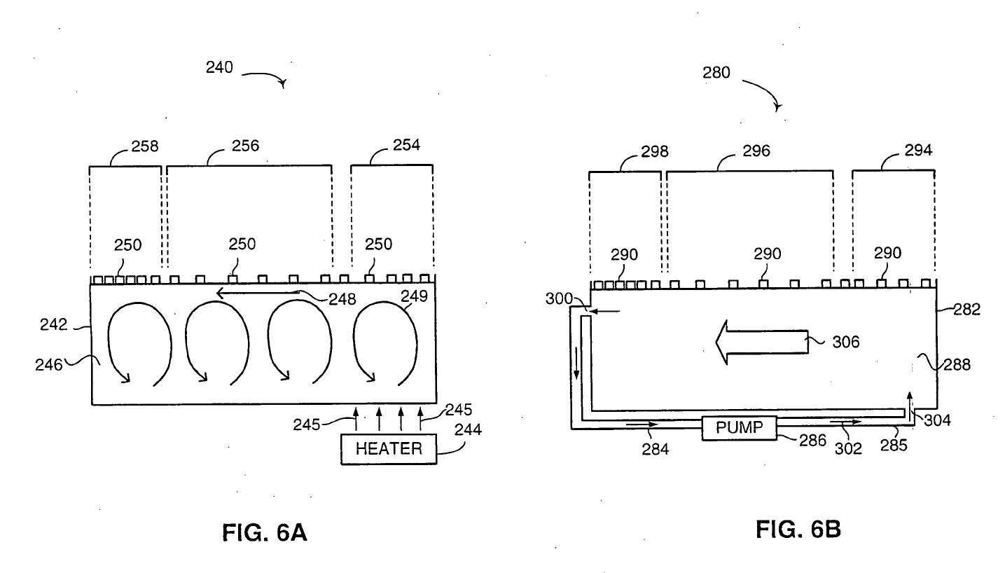

Flow unit 105 induces crystallites 110, whether grown in, or provided to, a portion of container 102, to move away from crystal introduction section 118 towards crystal transition section 120. Flow unit 105 induces a flow in liquid 108 which in turn induces crystallites 110 to move on the surface of liquid 108. Flow unit 105 is further described below with reference to FIGS. 6A and 6B. Besides the flow mechanisms described in FIGS. 6A and 6B, a flow can be induced, or can occur spontaneously, in container 102 from crystal introduction section 118 to crystalline sheet formation section 124 by a variety of mechanisms, with or without a flow unit, such as by optional flow unit 105. Such mechanisms may include a gravitational stream (e.g., by creating an outlet at the bottom of container 102), mechanical pumping, thermo-capillarity (e.g., by inducing the surface of liquid 108 to move from a hotter to a colder location), magneto-hydro-dynamics (by inducing a magnetic field and an electrical field, each perpendicular to one another, in liquid 108, if liquid 108 is a metal melt), mechanical waving, moving a solid track downstream, propulsion (i.e., propelling liquid 108 using a propeller), stirring or mixing (by causing a circular movement of the surface of liquid 108), or a combination thereof. The shape of container 102, further described below with reference to FIGS. 2A, 2B, 3A, 3B, 4A and 4B, also assists in inducing the movement of crystallites 110. The direction of movement of crystallites 110 is depicted by arrow 112. In crystal introduction section 118, crystallites 110 are located relatively close to one another such that the crystallites would have formed a crystalline sheet if crystalline sheet formation, or sintering, conditions were present and the crystallites remained in crystal introduction section 118. However, an early formation of a crystalline sheet in crystal introduction section 118 is undesirable. In general, since the conditions (i.e., temperature, pressure and the like) for crystal growth can be very similar to the conditions for crystalline sheet formation, in order to prevent crystallites 110 from forming a crystalline sheet, crystallites 110 continuously move, or are induced to move away, from crystal introduction section 118. In crystal transition section 120, crystallites 110 move or are induced to flow to another section of container 102, towards crystalline sheet formation section 124. If crystal transition section 120 is eliminated, crystallites 110 flow directly from crystal introduction section 118 to the adjacent crystalline sheet formation section 124. In such a configuration, the course of movement typifying crystal transition section 120 takes place either in the downstream part of crystal introduction section 118, or the adjacent upstream part of a crystalline sheet formation section 124, or in both such parts.

Crystallites in crystal introduction section 118 (either grown therein or provided thereto) will not be able to properly orientate themselves to form a crystalline sheet having a low density of sheet defects (namely, misorientations, holes or gaps), given the conditions present in section 118. Therefore, it is desirable to prevent crystalline sheet formation (i.e., sintering) in that section, as described below. In crystal transition section 120, the conditions, such as lower temperature or the flow rate of liquid 108, are such that no sintering occurs. It is noted that in crystal transition section 120, crystallites 110 are spread out and are not close enough to each other in order to form an oriented crystalline sheet. It is further noted that in crystal transition section 120, crystallites 110 move or are induced to move at a velocity faster than the velocity of their movement in crystal introduction section 118 or in crystalline sheet formation section 124.

While crystallites 110 are being introduced to crystal introduction section 118, especially if crystallites 110 are grown from liquid 108, some of crystallites 110 may sinter and join together while being misoriented with respect to one another, thus forming a non-oriented polycrystalline structure. Such a non-oriented structure is undesirable for forming a uniformly oriented crystalline sheet in crystal sheet formation section 124, since it will have more than one orientation. Thus, the conditions in crystal introduction section 118 should be maintained such that no sintering will occur. Alternatively, the rate of movement of crystallites 110 (i.e., the rate of the induced flow in liquid 108), can be increased in order to keep crystallites 110 spread out from one another, thereby preventing crystallites 110 from sintering and forming a non-oriented polycrystalline structure.

In crystalline sheet formation section 124, the velocity of crystallites 110 is reduced in order to allow crystallites 110 to self-orientate. Crystallites 110 are self-orientated when crystallites 110 are orientated next to each other in the same direction such that their edges are aligned together in an organized manner. As more crystallites 110 are induced to move to crystalline sheet formation section 124, crystallites 110 therein turn and rotate, due to the induced flow as well as due to the collisions between individual crystallites 110 as they are induced to move, until they reach a compact configuration. The compact configuration is a thermodynamic state requiring a substantial amount of kinetic energy for its alteration. In this respect crystallites 110 self-orientate themselves, according to their geometric shape. When crystallites 110 are orientated in a compact configuration, such that the edges of each crystal 110 are parallel and adjacent to one another, crystallites 110 may be considered to have formed an oriented mosaic-like tiled surface, as illustrated in sections 160, 182, 202 and 216 in FIGS. 2A, 3A, 4A and 5 respectively. At this point, each of crystallites 110 is at rest relative to one another, and the tiled surface of crystallites 110 may float at a constant velocity on the surface of liquid 108, or come to a complete stop thereon.

Since the conditions required to sinter crystallites 110 into a continuous crystalline sheet can be controlled in crystalline sheet formation section 124, crystallites 110 can be given the amount of time needed to properly self-orientate before those conditions are applied. In this manner, crystalline sheet defects, such as crystallite misorientations, gaps, holes and grain boundaries can be minimized and possibly prevented. In the above mentioned prior art systems disclosed by Li and Sunkara, and Angus, since the crystallites are grown and sintered in the same location, and since the crystal growth conditions and the crystal sintering conditions can be similar, grown crystallites will not have sufficient time to properly self-orientate before being sintered into an oriented crystalline sheet. Since the crystallites will not have had the time to properly self-orientate, crystal sheets formed in this manner will suffer from numerous defects of crystalline sheets. For example, some crystallites may be misorientated such that they “lean” on adjacent crystallites, and protrude from the two-dimensional plane of the sintered crystal sheet. Such misorentations can render the sintered sheet non-applicable for most industrial applications. Moreover, such misorientations can not be repaired by applying subsequent epitaxial growth conditions, since gaps will be filled in, in a misorientated manner, and the sheet defects will inevitably be passed on to additional epitaxially grown crystal layers.

Crystallites 110 can also be assisted in self-orientation by agitation, either ultrasonically, mechanically, magnetically or a combination thereof. Agitation causes crystallites 110 to rotate and turn, which assists in self-orientation. Ultrasonic agitation can be provided by an ultrasound unit (not shown), coupled with crystalline sheet formation section 124 of container 102, which applies ultrasound waves. Mechanical agitation can be provided by a mechanical unit (not shown), also coupled with crystalline sheet formation section 124 of container 102, which applies mechanical vibrations or waves to liquid 108 of container 102. Electromagnetic agitation can be provided by an electromagnetic unit (not shown), also coupled with crystalline sheet formation section 124 of container 102. The electromagnetic unit can generate a magnetic or electrical alternating induction, which can assist crystallites 110 in self-orientation, if crystallites 110 are sensitive to such an induction. In crystalline sheet formation section 124, crystallites 110 are close to one another, are substantially orientated in a common direction, and can form a uniformly oriented crystalline sheet if crystalline sheet formation conditions (i.e., temperature and pressure) are present therein. An optional guiding element placed in container 102 may further assist crystallites 110 in self-orientating, as further elaborated with reference to FIG. 5 below.

It is noted that certain crystal primitive plane forming geometries (e.g., rectangle, parallelogram, hexagon, triangle and the like) are better suited for forming a two-dimensional plane without substantial gaps or holes, while other plane forming geometries (e.g., pentagon, octagon, heptagon and the like) will most probably form a two-dimensional surface with gaps or holes between the compacted crystallites.

In an embodiment of the disclosed technique, once crystallites 110 have been self-orientated in crystalline sheet formation section 124, sintering conditions can be applied to crystalline sheet formation section 124 by a heater (not shown), or by creating a deposition environment on crystallites 110, as will be described hereinafter, in order to sinter crystallites 110. It is noted that crystallites 110 can also be sintered, or “welded” together, by using ultrasound waves. The ultrasound waves can cause crystallites 110, which are already in a compact configuration, to rub against one another and generate enough heat at the edges thereof to allow sintering between crystallites 110 to occur. Alternatively, heat can be applied by using a scanning energy beam, for example, a laser beam, an electron beam, lighting crystallites 110, using a hot filament and the like. Sintering the crystallites causes crystallites 110 to form a continuous crystalline sheet such that the grain boundaries between crystallites are no longer noticeable. Because crystallites 110 are allowed to self-orientate in crystalline sheet formation section 124 before sintering, the sintered crystalline sheet should be oriented and should also have a low density of gaps or holes. Since crystallites 110 are generally of the same substance, the formed crystalline sheet will inevitably be of the same substance as well. The continuous crystalline sheet can then be removed from container 102, for example, by using a net, and used. It is noted that a technique of material deposition can be applied to sinter crystallites 110, by filling-in, and thereby closing, the gaps (if any) between crystallites 110. Such a technique can be used with a suitable material deposition means or unit for depositing the material onto crystallites 110. For example, a delicate material deposition method like Molecular Beam Epitaxy (MBE) or Metal Organic Chemical Vapor Deposition (MOCVD) can be applied, or any other known material deposition technique. Generally, deposition techniques require heating of the substrate, thus the use of a deposition technique on crystallites 110 is likely to cause sintering thereof.

In another embodiment of the disclosed technique, once crystallites 110 have been self-orientated in crystalline sheet formation section 124, crystallites 110 can be removed from container 102 in crystal removal section 126, via track 114. Track 114 can be considered a substrate, or a surface, which can be clad with crystallites 110. Track 114 can be made of stainless steel, tantalum, molybdenum, steel, aluminum, copper alloys, paper, plastic, fabric, composite materials or any other suitable material which can be clad with crystallites 110. Track 114 can be made from a foil-forming material that can withstand the temperatures used in system 100 and which will not induce undesired doping or smearing to crystallites 110, or any other undesirable effects to crystallites 110 which could render them not useful for industrial applications. As track 114 may need to be curved or bent in order to enter and exit container 102, track 114 should be of sufficient mechanical strength so as to withstand substantial tensile stress and at the same time be elastic enough to enable curvature in the track.

Track 114 is provided to pre-processing unit 104, in the direction of arrow 116. As mentioned above, track 114 can refer to a mere conveyer belt, a substrate in the form of a conveyer belt or a substrate placed upon a conveyer belt. As new track material can be continuously provided to pre-processing unit 104, track 114 can be thought of as a “roll-to-roll” or “endless” track. Pre-processing unit 104 pre-processes track 114. Pre-processing may include, for example, perforating track 114, cleaning track 114 using wet chemicals, drying track 114, applying an argon plasma on track 114 for physical cleaning, sputtering track 114 with a particular chemical element or molecule, altering the temperature of track 114, indenting track 114 at predetermined space intervals and the like. Sputtering, deposition or an equivalent coating of track 114 may be applied to coat track 114, for example, with a primer material, to enable bonding or gluing of the crystallites 110 (or a sheet formed from crystallites 110) to track 114 or a substrate thereof. Rollers 122_{A} and 122_{B} guide track 114 from pre-processing unit 104 into container 102. Roller 122_{C} guides track 114 into liquid 108, underneath crystallites 110 and out of container 102. Roller 122_{D} guides track 114 towards post-processing unit 106.

In crystal removal section 126, rollers 122_{B}, 122_{C} and 122_{D} guide track 114 underneath crystallites 110. Track 114 generally proceeds at a rate compatible with the flow rate of crystallites 110 (which is slower than their flow rate before they reach track 114), thereby allowing crystallites 110 to be collected onto (or to “climb” onto) track 114. The angle formed between track 114 and the surface of liquid 108 in FIG. 1 is depicted by angle 121. Angle 121 is selected such that the slope of track 114 is gradual when crystallites 110 are removed from liquid 108. A gradual slope ensures that the tiled surface of crystallites 110 will not lose its orientation as it is removed from liquid 108 and that crystallites 110 will not slip off of track 114 back into container 102. Crystallites 110 on track 114 are provided to post-processing unit 106, which post-processes either crystallites 110, track 114 or both. Post-processing can include sintering crystallites 110, gluing or sintering crystallites 110 to a substrate, bonding crystallites 110, growing epitaxial layers on the formed continuous crystalline sheet, doping the formed continuous crystalline sheet, metallizing the formed continuous crystalline sheet, performing known micro-fabrication processes (e.g., lithography, etching and deposition), sectioning track 114 and the like. According to the disclosed technique, since crystallites 110 are given sufficient time and space to self-orientate with respect to each other, they can thus form a uniformly oriented two-dimensional mosaic-like tiled surface. After crystallites 110 have been sintered, it is possible that a plurality of adjacent crystallites of crystallites 110 are self-orientated, yet gaps remain in between the crystallites, thereby resulting in the presence of gaps in the sintered crystalline sheet. In such a case, post-processing unit 106 can execute epitaxial crystal growth on the sintered crystalline sheet, which will thereby fill in the gaps in an oriented manner in the crystalline sheet. The crystalline sheet thus formed will have a very low amount of sheet defects, or possibly none.

After post-processing, crystallites 110 are formed into a crystalline sheet 128. Crystalline sheet 128 is guided along track 114 in the direction of arrow 130, and may then be removed from track 114 and used. Crystalline sheet 128 may also be removed by cutting the portion of track 114 on which it is located. Since track 114 may continue for very long, and virtually limitless, distances, very large dimension crystal sheets of high quality can be formed. For example, for practical purposes the width of track 114 can vary from a few millimeters to tens of centimeters, and its length from several centimeters to hundreds of meters. Large crystal sheets bounded only by the width of the track 114 and virtually “endless” in length along track 114 can thus be manufactured. Notably, as the width and length of track 114 are virtually limitless in comparison to any known industrial requirement for crystal dimensions, track 114 can be adapted to meet any such requirement, and the size of crystalline sheet 128 can provide for any required large size crystal.

Reference is now made to FIGS. 2A and 2B, which are respectively a top view and a side view of an embodiment of the container of FIG. 1, generally referenced 150, constructed and operative in accordance with another embodiment of the disclosed technique. From a top view, container 150 has a broadened middle section 158 and includes a lobed section 156 and a tapered section 160. From a side view, container 150 is rectangular in shape, and as such, lobed section 156 and tapered section 160 are no different in depth than the rest of container 150. Container 150 is filled with a liquid 153, on which crystallites 154 float. A flow is induced in liquid 153 by a flow unit (not shown), and is depicted by arrow 152. The direction of arrow 152 depicts the direction of the flow.

In FIGS. 2A and 2B, the three sections 156, 158 and 160, respectively correspond to a crystal introduction section 156, a crystal transition section 158, and a crystalline sheet formation section 160, which tapers from crystal transition section 158. In crystal introduction section 156, crystallites are grown, or provided thereto. It is noted that crystal introduction section 156 is lobed shaped, as seen from its top view in FIG. 2A, and that crystallites in crystal introduction section 156 are spaced relatively close to one another. Due to the direction of the flow, the quantity of crystallites in crystal introduction section 156, and its lobe shape, crystallites which are grown in, or provided to, crystal introduction section 156 are induced to move away from crystal introduction section 156 towards crystal transition section 158. In crystal transition section 158, crystallites are induced to move towards crystalline sheet formation section 160. Due to the broadened nature of crystal transition section 158, crystallites in crystal transition section 158 are spaced substantially far apart from one another. The conditions in crystal transition section 158 are such that no sintering of crystallites 154 can occur, for example by providing a cooler environment. In crystalline sheet formation section 160, due to the direction of the flow and the tapering nature of crystalline sheet formation section 160, and the tapering width of crystal transition section 158, crystallites 154 can self-orientate and can be spaced substantially close to one another in preparation for forming an oriented crystalline sheet. It is noted that the tapered shape of crystalline sheet formation section 160 facilitates an ordered arrangement of crystallites 154 in a compact configuration as the first crystal to arrive at the end of tapered crystalline sheet formation section 160 will acquire a particular orientation due to the pointed shape of crystalline sheet formation section 160. As other crystallites arrive at crystalline sheet formation section 160, each crystal will acquire a particular orientation parallel to the orientation of that first crystal. The interior angle formed by the tapered end of crystalline sheet formation section 160 can be selected depending on the geometric shape of crystallites 154. For example, since crystallites 154 are rectangular in shape, the interior angle formed by the tapered end of crystalline sheet formation section 160 is substantially 900.

Reference is now made to FIGS. 3A and 3B, which are respectively a top view and a side view of another embodiment of the container of FIG. 1, generally referenced 170, constructed and operative in accordance with a further embodiment of the disclosed technique. From a top view, container 170 is rectangular in shape, having a tapered section 182 at one end. From a side view, container 170 is substantially rectangular in shape, having a curved floor 171 such that container 170 has a deeper middle section 180 and shallow side sections 178 and 182. Container 170 is filled with a liquid 174, on which crystallites 176 float. A flow is induced in liquid 174 by a flow unit (not shown) or by other flow inducing means (e.g. gravitation, thermal convection or magneto-dynamics), and is depicted by arrow 172. The direction of arrow 172 depicts the direction of the flow.

In FIGS. 3A and 3B, the three sections 178, 180, and 182, respectively correspond to a crystal introduction section 178, which is shallow, a crystal transition section 180, which is deeper, and a crystalline sheet formation section 182, which is also shallow. In crystal introduction section 178, crystallites are grown, or provided thereto. It is noted that crystallites in crystal introduction section 178 are spaced relatively close to one another. Due to the direction of the flow, the quantity of crystallites in crystal introduction section 178, and the relative shallow depth therein, crystallites 176 are induced to move away from crystal introduction section 178 towards crystal transition section 180. Due to the relative shallow depth of crystal introduction section 178, this induced movement is at a relatively fast rate, as the flow velocity of liquid 174 is inversely proportional to the depth of liquid 174 in container 170. In crystal transition section 180, crystallites 176 are induced to move towards crystalline sheet formation section 182. Due to curved floor 171, which causes container 170 to have relative deep depth in the center, crystallites 176 in crystal transition section 180 are induced to move at a relatively slow rate. The conditions in crystal transition section 180 are such that no sintering of crystallites 176 can occur. In crystalline sheet formation section 182, due to the direction of the flow, the tapered shape of crystalline sheet formation section 182, and the relative shallow depth therein which increases the flow rate of liquid 174, crystallites 176 tend to congregate, and thus can self-orientate and be spaced substantially close to one another in preparation for forming an oriented crystalline sheet. It is noted that the tapered shape of crystalline sheet formation section 182 facilitates an ordered arrangement of crystallites 176 in a compact configuration as the first crystal to arrive at the tapered end of crystalline sheet formation section 182 will acquire a particular orientation due to the pointed shape of crystalline sheet formation section 182. As other crystallites arrive at crystalline sheet formation section 182, each crystal will acquire a particular orientation relative to the orientation of that first crystal. It is noted that the interior angle formed by the tapered end of crystalline sheet formation section 182 can be selected depending on the shape of crystallites 176. For example, since crystallites 176 are rectangular in shape, the interior angle formed by the tapered end of crystalline sheet formation section 182 is substantially 900.

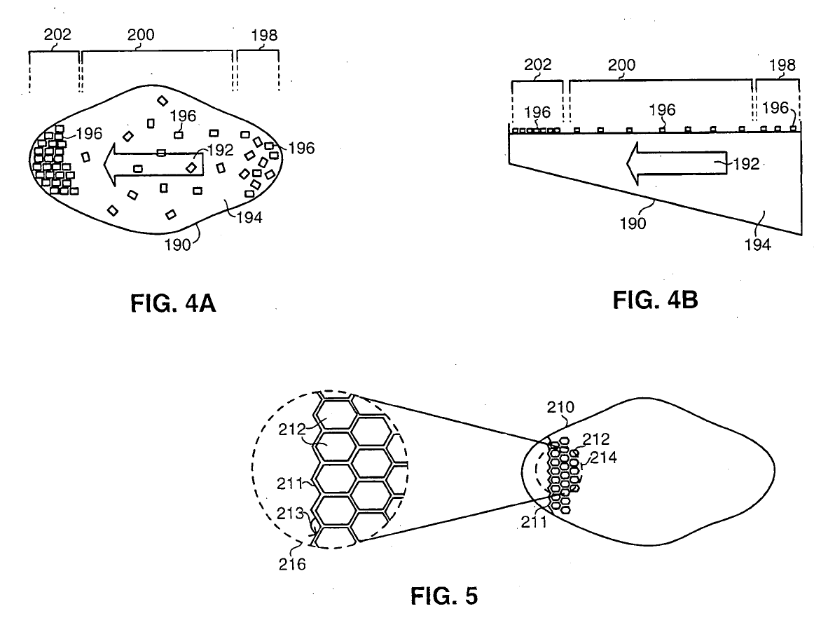

Reference is now made to FIGS. 4A and 4B, which are respectively a top view and a side view of a further embodiment of the container of FIG. 1, generally referenced 190, constructed and operative in accordance with another embodiment of the disclosed technique. From a top view, container 190 is lozenge-like in shape. From a side view, container 190 is substantially trapezoidal-like in shape, having a sloped floor such that one end of container 190 is deeper than the other end. Container 190 is filled with a liquid 194, on which crystallites 196 float. A flow is induced in liquid 194 by a flow unit (not shown) or by other means (e.g., gravitation, thermal convection or magneto-dynamics), and is depicted by arrow 192. The direction of arrow 192 depicts the direction of the flow.

In FIGS. 4A and 4B, three sections are depicted: crystal introduction section 198, crystal transition section 200 and crystalline sheet formation section 202. In crystal introduction section 198, crystallites 196 are grown, or provided thereto. Crystallites 196 in crystal introduction section 198 are spaced substantially close to one another. Due to the direction of the flow, the quantity of crystallites in crystal introduction section 198, and the relative deep depth therein, crystallites 196 are induced to move away from crystal introduction section 198 towards crystal transition section 200. Due to the relative deep depth of crystal introduction section 198, the induced movement is at a relatively slow rate, as the flow velocity of a liquid is inversely proportional to the depth of the liquid. In crystal transition section 200, crystallites are induced to move towards crystalline sheet formation section 202. Due to the sloped floor of container 190, crystallites 196 in crystal transition section 200 are induced to move at a gradually accelerating rate as they approach crystalline sheet formation section 202. In crystalline sheet formation section 202, due to the direction of the flow and the relative shallow depth therein, crystallites 196 congregate and can self-orientate and be spaced substantially close to one another in preparation for forming an oriented crystalline sheet. It is noted that the container of FIG. 1 can also have a shape which is derived from a combination of any of the shapes depicted in FIGS. 2A, 2B, 3A, 3B, 4A and 4B. For example, the container of FIG. 1 can have, from a top view, a broadened middle section, a lobed section and a tapered section (as in FIG. 2A), and from a side view, a rectangular shape, having a sloped floor such that one end of the container is deeper than the other end (as in FIG. 4B).

Reference is now made to FIG. 5, which is an enlarged view of a guiding element, used in the container of FIG. 4A, generally referenced 210, constructed and operative in accordance with a further embodiment of the disclosed technique. It is noted that the guiding element depicted in FIG. 5 is an optional element. Container 210 includes crystallites 212, which are elongated in shape, and a guiding element 211, having a zigzagged boundary. Crystallites 212 are in a crystalline sheet formation section of container 210 whereby they have already self-orientated and form an oriented mosaic-like tiled surface. In FIG. 5, a section 214 of container 210 is enlarged as section 216 to depict the zigzagged boundary of guiding element 211 and to show how this boundary shape assists in the self-orientation of crystallites 212. It is noted that guiding element 211 can be used in the container of FIGS. 2A and 3A. As can be seen from section 216, the side of guiding element 211 facing crystallites 212 is angled in a zigzag manner at a predetermined angle 213. Predetermined angle 213 is chosen to best suit the geometric shape of crystallites 212 such that guiding element 211 induces their self-arranging in compatible orientations while they flow and crowd toward the narrowing end of container 210. When the first of crystallites 212 to arrive in crystalline sheet formation section of container 210 encounter, by coming in contact with, guiding element 211, these crystallites will acquire a particular orientation due to the zigzag shape of the facing boundary of guiding element 211. These crystallites will essentially “dock” at guiding element 211. As more crystallites arrive in the crystalline sheet formation section of container 210, these crystallites will acquire an orientation relative to the orientation of the first crystallites to arrive in that section (as they will “dock” at those first crystallites), thereby giving all the crystallites in that section a compact configuration.

Reference is now made to FIG. 6A, which is a schematic illustration of a system, generally referenced 240, depicting an embodiment of the flow unit of FIG. 1, constructed and operative in accordance with another embodiment of the disclosed technique. System 240 includes a container 242 and a heater 244. Container 242 contains a liquid 246 upon which crystallites 250 float. System 240 depicts three sections: a crystal introduction section 254, a crystal transition section 256 and a crystalline sheet formation section 258. A flow is induced in liquid 246 in the general direction of an arrow 248. In FIG. 6A, heater 244 is located directly under crystal introduction section 254, however it may be also immersed in liquid 246 in crystal introduction section 254. Heater 244 may also be placed above or to the side of crystal introduction section 254.

In FIG. 6A, the induced flow is caused by thermal convection resulting from heat (depicted by arrows 245) emanating from heater 244 directly under crystal introduction section 254. As crystallites 250 are grown in, or provided to, crystal introduction section 254, heat is applied to that section by heater 244. It is noted that the heat may be also used for creating crystal growth conditions (i.e., sufficient heat) confined to crystal introduction section 254. As the heat rises into liquid 246, particles in liquid 246 located directly beneath heater 244 will begin to rise due to the phenomenon of thermal convection. As these heated particles rise, cooler particles in liquid 246 will move into the location the heated particles occupied, thereby forming a convection current, as depicted by an arrow 249. This convection current resembles a whirlpool and causes liquid 246 to form multiple convection currents. As the convection currents flow in a manner seen as counter clockwise in FIG. 6A, a flow will be induced in liquid 246 in the general direction of arrow 248. As heat is only applied to crystal introduction section 254, a convection current in the direction of arrow 248 will form whereby heated liquid particles in that section will move towards crystalline sheet formation section 258, and cool liquid particles in crystalline sheet formation section 258 will move towards crystal introduction section 254 in a cyclical manner. Since crystallites 250 float on the surface of liquid 246, as liquid 246 thermally convects, crystallites 250 will be induced to move from crystal introduction section 254, through crystal transition section 256 towards crystalline sheet formation section 258.

Reference is now made to FIG. 6B, which is a schematic illustration of a system, generally referenced 280, depicting another embodiment of the flow unit of FIG. 1, constructed and operative in accordance with a further embodiment of the disclosed technique. System 280 includes a container 282 and a pump 286. Container 282 contains a liquid 288 upon which crystallites 290 float. Pump 286 is coupled with container 282 by intake pipe 284 and outtake pipe 285. System 280 depicts three sections: a crystal introduction section 294, a crystal transition section 296 and a crystalline sheet formation section 298. A flow is induced in liquid 288 in the direction of an arrow 306.

In FIG. 6B, the induced flow is caused by pump 286 which pumps in liquid 288 at an intake valve 300 and pumps out the liquid at an outtake valve 304. Liquid 288 is pumped in the direction of an arrow 302. It is noted that intake valve 300 and outtake valve 304 can be placed at different locations on container 282, depending on the shape of the container. As crystallites 290 are grown in, or provided to, crystal introduction section 294, liquid particles in that section are pumped towards crystalline sheet formation section 298 by pump 286. As pump 286 pumps liquid 288 in the direction of arrow 302, a current in the direction of arrow 306 will form whereby liquid particles in crystal introduction section 294 will move towards crystalline sheet formation section 298 in a cyclical manner. Since crystallites 290 float on the surface of liquid 288, as the current of liquid 288 flows, crystallites 290 will be carried away from crystal introduction section 294, through crystal transition section 296 towards crystalline sheet formation section 298.

Reference is now made to FIG. 7, which is a schematic illustration of a group-III metal nitride crystalline sheet formation system, generally referenced 310, constructed and operative in accordance with another embodiment of the disclosed technique. Group-III metal nitride crystalline sheet formation system 310 includes a container 312, a pre-processing unit 314, a pump 344, a heater 360, an intake pipe 341, an outtake pipe 343, a nitrogen plasma generating unit 350 (i.e., a nitrogen plasma generator), a vacuum chamber 354, a vacuum pump 356, a post-processing unit 316, a track 324 and rollers 334_{A}, 334_{B}, 334_{C} and 334_{D}. Container 312 contains a group-III metal melt 318. As an example, group-III metal nitride crystalline sheet formation system 310 will be described with reference to the formation of GaN crystalline sheets. As such group-III metal melt 318 will be referred to as a gallium melt and will be referenced to as such. Container 312 can have a shape similar to container 170 (FIGS. 3A and 3B). Container 312 can also have a shape similar to container 150 (FIGS. 2A and 2B) or container 190 (FIGS. 4A and 4B). Pre-processing unit 314, post-processing unit 316, track 324, rollers 334_{A}, 334_{B}, 334_{C} and 334_{D}, and pump 344, are optional components in group-III metal nitride crystalline sheet formation system 310.

Arrows in rollers 334_{A}, 334_{B}, 334_{C} and 334_{D} indicate the respective direction in which each roller turns. Pump 344 is coupled with container 312 via intake pipe 341 and outtake pipe 343. Vacuum pump 356 is coupled with vacuum chamber 354. Track 324 is coupled with pre-processing unit 314, container 312, rollers 334_{A}, 334_{B}, 334_{C} and 334_{D}, and post-processing unit 316. Track 324 is configured to pass through pre-processing unit 314 and post-processing unit 316. Track 324 is also configured to enter and exit container 312, via rollers 334_{A}, 334_{B}, 334_{C} and 334_{D}. Roller 334_{C} is located within container 312. Container 312, pump 344, intake pipe 341, outtake pipe 343, heater 360, nitrogen plasma generating unit 350, a section of track 324 and rollers 334_{A}, 334_{B}, 334_{C} and 334_{D} are all located inside vacuum chamber 354. It is noted that vacuum chamber 354 is built in a manner such that track 324 can enter and exit vacuum chamber 354 without having the pressure of vacuum chamber 354 altered. Alternatively, track 324 can be separated into adjacent tracks, for example an endless track located inside vacuum chamber 354 and another track located outside vacuum chamber 354. Nitrogen plasma generating unit 350 can be a magneto-inductive plasma, a radio frequency plasma, a transformer type low frequency plasma generator, or an electron cyclotron resonance (ECR) plasma source, each of which generates nitrogen ions in the gas state. It is noted that the pressure inside vacuum chamber 354 may be reduced by vacuum pump 356 to sub-atmospheric pressures, for example, to 2-20 Pa (pascals). It is also noted, as mentioned above, that group-III metal nitrides include AlN, GaN and InN.

Group-III metal nitride crystalline sheet formation system 310 includes four sections: a crystal growth section 327, a crystal transition section 328, a crystalline sheet formation section 330 and a crystal removal section 332. Crystal removal section 332 is optional. Crystal transition section 328 is only described for demonstrative purposes, whereas it can be of minimal length or eliminated altogether, as crystal growth section 327 can be adjacent to crystalline sheet formation section 330 without any spacing there between.

Sections 327, 328 and 330 of group-III metal nitride crystalline sheet growth system 310 can each be in the form of a separate container (not shown), and not sections of a single container (as in container 312). For example, section 327 can be a crystal growth container, section 328 can be a crystal transition container, and section 330 can be a crystalline sheet formation container. If desired, the pressure and temperature conditions in each of the containers can be controlled separately, in order to apply suitable conditions for each of the different stages of group-III metal nitride crystalline sheet growth system 310. The separate containers can be connected, for example via a duct, through which gallium melt 318 can flow from one container to another. Alternatively, the separate containers can be completely segregated, and arranged such that gallium melt 318 is allowed to flow between the separate containers (e.g., due to gravitation, if the crystal growth container is placed higher than the crystal transition container, and the crystallites are allowed to move from the crystal growth container to the crystal transition container).

In crystal growth section 327, nitrogen plasma generating unit 350 directs active nitrogen (N or N⁺, as depicted by arrows 352) towards the surface of gallium melt 318. At the same time, heater 360 applies heat (depicted by arrows 362) to the portion of gallium melt 318 located in crystal growth section 327 and the pressure inside vacuum chamber 354 is reduced to 10⁻³ Pa. When the temperature of gallium melt 318 reaches approximately 750° C., GaN crystallites 320 will begin to form on the surface of gallium melt 318, as gallium and nitrogen react to form GaN crystallites at this temperature (the temperature for growth can be set for example between 750° C. and 950° C.). Due to the chemical and physical properties of GaN crystallites with respect to gallium melt 318, at least a portion of the GaN crystallites will float on the surface of gallium melt 318. It is noted that in crystal growth section 327, GaN crystallites 320 that are formed are located relatively close to one another. It is furthermore noted that at the temperature and pressure conditions in crystal growth section 327 (i.e., 10⁻³ Pa and 750° C.), the edges of GaN crystallites 320 can sinter or be sintered to form a continuous GaN crystalline sheet if GaN crystallites 320 are not moved out of that section within an adequate amount of time. In another embodiment of the disclosed technique, GaN crystallites 320 can be grown in a different location (other than container 312), and physically provided to container 312 at section 327.

According to another embodiment of the disclosed technique, GaN crystallites 320 are small in size (i.e., on the order of micrometers), and therefore, in general, have a low density of dislocation defects (i.e., lower than 10³ dislocations/cm²). As such, when GaN crystallites 320 are sintered, in crystalline sheet formation section 330, into a continuous crystalline sheet, the formed sheet will also have a low density of dislocations. Thus, by introducing (either growing or providing) small GaN crystallites to crystal growth section 327, the quality of the formed crystalline sheet is improved, and the dislocation defect density thereof is significantly reduced, rendering the formed crystalline sheet suitable for industrial use.

If GaN crystallites 320 are not timely moved out of crystal growth section 327, then GaN crystallites 320 may sinter to form a defected GaN crystalline sheet. In general, this GaN crystalline sheet will have a high density of crystalline sheet defects (mainly misorientations), because GaN crystallites 320 formed in crystal growth section 327 will not have sufficient time to properly self-orientate before sintering together to form a uniform continuous GaN crystalline sheet. In order to prevent GaN crystallites 320 from sintering into a defected GaN crystalline sheet, a flow is induced in gallium melt 318, in the direction of an arrow 322. The induced flow in gallium melt 318 in turn induces GaN crystallites 320 to have movement, thus preventing possible sintering. This induced flow causes GaN crystallites 320 to move away from crystal growth section 327 towards crystal transition section 328. In crystal transition section 328, the conditions, such as lower temperature, are such that no crystalline sheet formation occurs. The flow is induced by pump 344, which pumps gallium melt 318 into intake pipe 341, via intake valve 346, towards outtake valve 348, via outtake pipe 343. Gallium melt 318 is pumped in the direction of an arrow 342. Since only one side of container 312 is heated, the flow is further induced by thermal convection or microcapillarity that occurs on the surface of gallium melt 318. As the heat from heater 360 rises into gallium melt 318, gallium particles in the melt located directly beneath heater 360 will begin to rise due to their increase in temperature. As these heated particles rise, cooler particles in gallium melt 318 will move into the location the heated particles occupied, thereby forming a convection current. As heat is only applied to crystal growth section 327, a convection current (or thermo-capillary current) in the direction of arrow 322 will form whereby heated gallium particles in that section will move towards crystalline sheet formation section 330, and cool gallium particles in crystalline sheet formation section 330 will move towards crystal growth section 327 in a cyclical manner. The inducement of the flow may be achieved by means other than pump 344 or heater 360, for example by means similar to those mentioned above in reference to FIG. 1 (e.g., gravitation, thermo-capillarity, magneto-dynamics, mechanical waving, stirring or mixing, or a combination thereof). The flow may also be induced due to the shape of container 312. Since the ends of container 312 can be shallower in depth than the center of the container (i.e., if the shape of container 312 resembles the shape of container 170 of FIGS. 3A and 3B), GaN crystallites 320 can move out of crystal growth section 327 at a relatively fast rate towards crystal induced movement section 328, where the rate of movement of GaN crystallites 320 is reduced due to the increase in depth of the container.

In crystal transition section 328, GaN crystallites 320 are induced to flow to another section of container 312, towards crystalline sheet formation section 330. In crystal transition section 328, GaN crystallites 320 are spread out and are not close enough to form a continuous GaN crystalline sheet. Furthermore, the temperature conditions in that section are controlled such that GaN crystallites 320 will be prevented from sintering to form a continuous GaN crystalline sheet. In crystalline sheet formation section 330, GaN crystallites 320 are allowed to self-orientate. If crystal transition section 328 is eliminated, GaN crystallites 320 flow directly from crystal growth section 327 to the adjacent crystalline sheet formation section 330. In such a configuration, the course of movement typifying crystal transition section 328 takes place either in the downstream part of crystal growth section 327, or in the adjacent upstream part of crystalline sheet formation section 330, or in both such parts.

An optional guiding element (not shown), used in container 312, described above with reference to FIG. 5, can be used to further assist GaN crystallites 320 in self-orientating. GaN crystallites 320 can also be assisted in self-orientation by agitation, such as mentioned above with reference to FIG. 1 (e.g., ultrasonically, mechanically or magnetically). In crystalline sheet formation section 330, GaN crystallites 320 are close to one another, are substantially orientated in a common direction, and can form a GaN crystalline sheet if GaN crystalline sheet formation conditions are present therein.

In an embodiment of the disclosed technique, once GaN crystallites 320 have been self-orientated in crystalline sheet formation section 330, heat can be applied to GaN crystallites 320, in crystalline sheet formation section 330, by a heater (not shown), in order to sinter the GaN crystallites. Sintering the GaN crystallites causes GaN crystallites 320 to form a uniformly oriented continuous GaN crystalline sheet, such that the grain boundaries between crystallites 320 are no longer noticeable. Since the GaN crystallites were allowed to self-orientated themselves in crystalline sheet formation section 330, when the GaN crystallites are sintered, the continuous GaN crystalline sheet should have a low density of crystalline sheet defects. The continuous GaN crystalline sheet can then be removed from container 312, for example, by using a net or a track, and used.

In another embodiment of the disclosed technique, once GaN crystallites 320 have been self-orientated in crystalline sheet formation section 330, GaN crystallites 320 can be removed from container 312 in crystal removal section 332 via track 324. Track 324 can be considered a substrate, a surface, or a platform on which GaN crystallites 320 will be deposited or collected. Track 324 can serve as a substrate made of a conducting, a semi-conducting, or a dielectric material. For example, track 324 can be made of stainless steel. Track 324 is provided to pre-processing unit 314, in the direction of arrow 326. As new track material can be continuously provided to pre-processing unit 314, track 324 can be thought of as a “roll-to-roll” or “endless” track. Track 324 can be made of a foil-forming material which can withstand the temperatures and pressures used in system 310 and which will not induce undesired doping or smearing to GaN crystallites 320, or any other undesirable effects which may render GaN crystallites 320 not useful in industrial applications. Track 324 should be of sufficient mechanical strength so as to withstand substantial tensile stress and at the same time be elastic enough to enable curvature of the track. Track 324 can be made of tantalum, molybdenum, steel, stainless steel, aluminum, copper alloys, graphite fabric and the like.

Pre-processing unit 314 pre-processes track 324. Pre-processing may include, for example, perforating track 324, cleaning track 324 using wet chemicals, drying track 324, applying an argon plasma on track 324 for physical cleaning, sputtering track 324 with GaN crystals, altering the temperature of track 324, indenting track 324 at predetermined space intervals, and the like. Sputtering, deposition, or an equivalent coating of track 324, may be applied to coat track 324, for example with a primer material, to enable bonding or gluing of the GaN crystallites 320 (or a sheet formed from GaN crystallites 320) to track 324 or a substrate thereof. The coating can include for example amorphous or polycrystalline GaN deposited on the surface of track 324. Rollers 334_{A} and 334_{B} guide track 324 from pre-processing unit 314 into container 312. Roller 334_{C} guides track 324 into gallium melt 318, underneath GaN crystallites 320 and out of container 312. Roller 334_{D} guides track 324 towards post-processing unit 316.

In crystal removal section 332, rollers 334_{B}, 334_{C} and 334_{D} guide track 324 underneath GaN crystallites 320. Track 324 generally proceeds at a rate slower than the flow rate of GaN crystallites 320, thereby allowing GaN crystallites 320 to be collected onto track 324. The angle formed between track 324 and the surface of gallium melt 318 in FIG. 7 is depicted by angle 336. Angle 336 is selected such that the slope of track 324 is gradual when GaN crystallites 320 are removed from gallium melt 318. A gradual slope ensures that GaN crystallites 320 will not lose their orientation as they are removed from gallium melt 318 and that they will not slip off of track 324 back into container 312. GaN crystallites 320 on track 324 are provided to post-processing unit 316, which post-processes either GaN crystallites 320, track 324 or both. Post-processing can include sintering GaN crystallites 320, sectioning track 324, growing epitaxial films on GaN crystallites 320, growing hetero-epitaxial structures thereon, depositing a row of conducting and dielectric thin films of different substances, and the like. After post-processing, GaN crystallites 320 are formed into an oriented continuous GaN crystalline sheet 338 (either sectioned or not). Crystalline sheet 338 is guided along track 324 in the direction of arrow 340, and may then be removed from track 324. Alternatively, crystalline sheet 338 can be transformed into a semiconductor device structure (e.g., a photovoltaic cell, a transistor or a diode). Crystalline sheet 338 may also be removed by cutting the portion of track 324 on which it is located. Since track 324 is “endless,” very large dimension GaN crystal sheets, virtually “endless” in length, of high quality can be grown.

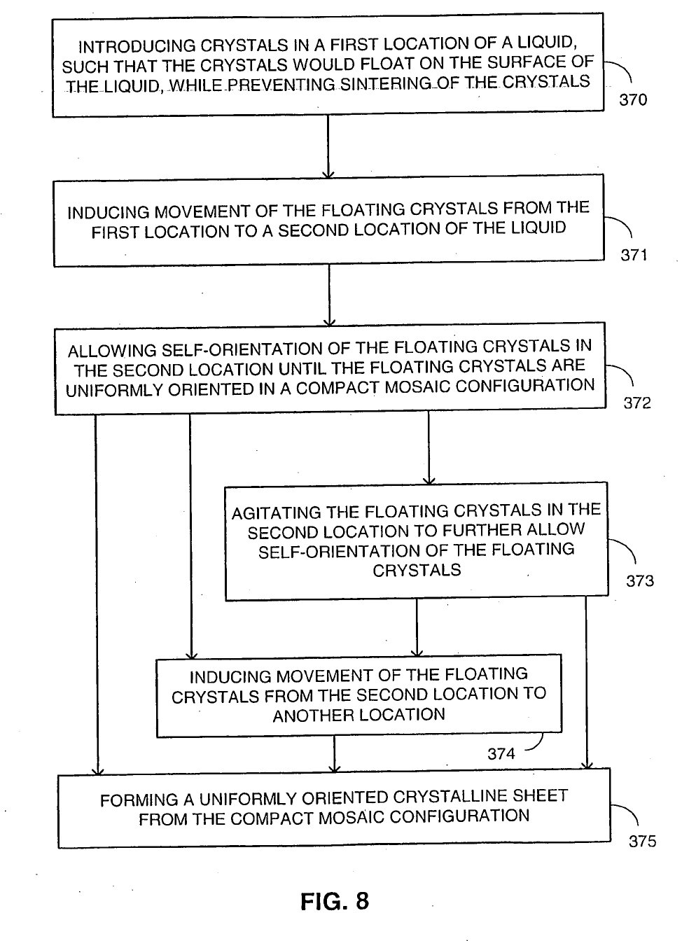

Reference is now made to FIG. 8, which is a schematic illustration of a method for forming a crystalline sheet, operative in accordance with a further embodiment of the disclosed technique. In procedure 370 a plurality of crystallites are introduced in a first location of a liquid. The liquid has chemical and physical properties with respect to the crystallites, such that at least a portion of the crystallites are floating crystallites which float on the surface of the liquid, for example through gravitation, surface tension properties, amphiphilic properties and the like. The crystallites can be grown from the liquid, for example, as described with reference to FIG. 7, where GaN crystallites are grown from a gallium melt using a nitrogen plasma. Alternatively, the crystallites can be grown in a different location (other than the liquid), and physically provided to the first location of the liquid (i.e., already grown crystallites are provided to the first location of the liquid). The crystallites should be introduced to the first location such that only a single layer of the crystallites will be present on the surface of the liquid in the first location. During procedure 370, sintering of the floating crystallites in the first location is prevented. Crystalline sheet formation should be prevented in the first location of the liquid because crystallites in that location, either grown therein or provided thereto, will not be able to properly orientate themselves to form a uniformly oriented crystalline sheet having a low density of crystalline sheet defects, if the temperature and pressure conditions present therein are similar to crystal growth conditions.

In procedure 371, the floating crystallites in the first location of the liquid are induced to move to a second location of the liquid. The floating crystallites can be induced to move by any suitable means, such as by thermally convecting the liquid in a direction pointing from the first location to the second location of the liquid. The crystallites can also be induced to move by circulating the liquid via a pump. The crystallites can furthermore be induced to move by a applying a gravitational stream, thermo-capillarity, applying an electromagnetic field, mechanical waving, propelling, stirring, mixing, applying thermal convection, pumping, movement of a solid track downstream, or means described in reference to FIG. 1, or any combination thereof.

In procedure 372, the floating crystallites in the second location of the liquid are allowed to self-orientate, until the floating crystallites are uniformly oriented in a compact mosaic configuration. The floating crystallites are induced to self-orientate due to the continuous flow of the liquid and the induced movement mentioned in procedure 371.

In procedure 373, the floating crystallites in the second location of the liquid are agitated, either ultrasonically, mechanically or electromagnetically, as described above with reference to FIG. 1, or a combination thereof, to further allow self-orientation of the floating crystallites. It is noted that procedure 373 is optional, and that the method depicted in FIG. 8 can proceed directly from procedure 372 to procedure 374 (or to procedure 375).

In procedure 374, the self-orientated crystallites in the second location are induced to move to another location. The other location can be a third location of the liquid, or a location located outside the liquid. It is noted that procedure 374 is optional, and that the method depicted in FIG. 8 can proceed directly from procedure 372, or from procedure 373, to procedure 375.

In procedure 375, a uniformly oriented crystalline sheet is formed from the floating crystallites which are in a compact mosaic configuration. This crystalline sheet should have a low density of crystalline sheet defects. Procedure 375 can include sintering of the floating crystallites while they are in the compact mosaic configuration, for example by applying heat to the floating crystallites (e.g., by using a heater, by using a laser beam, by lighting the crystallites, by using a hot filament, or by using an electron beam), or by other means described with reference to FIG. 1. Alternatively, sintering of the floating crystallites can be performed by depositing a suitable material onto the floating crystallites. A technique of material deposition can be used to sinter the floating crystallites, by filling in, and thereby closing, the gaps (if any) between the floating crystallites. For example, such a deposition technique can be a delicate material deposition method, like Molecular Beam Epitaxy (MBE) or Metal Organic Chemical Vapor Deposition (MOCVD), or any other known material deposition technique. Generally, deposition techniques require heating of the substrate, thus the use of a deposition procedure on the floating crystallites is likely to cause sintering thereof.

If procedure 374 is executed, then the crystalline sheet formation in procedure 375 is executed in the other location. If procedure 374 is not executed, then the crystalline sheet formation in procedure 375 is executed in the second portion of the liquid.

The method depicted in FIG. 8 can further include any of the procedures selected from the list consisting of: gluing the uniformly oriented crystalline sheet to a substrate, sintering the uniformly oriented crystalline sheet to a substrate, growing epitaxial layers on top of the uniformly oriented crystalline sheet, doping the uniformly oriented crystalline sheet, metallizing the uniformly oriented crystalline sheet, sectioning the uniformly oriented crystalline sheet, performing micro-fabrication processes on the uniformly oriented crystalline sheet, and the like.

It is noted that before procedure 375, attaching of the floating crystallites in the compact mosaic configuration (i.e., the arranged crystallites) can be performed. Attaching of the floating crystallites can be performed according to at least one of the following procedures: sintering the arranged crystallites, gluing the arranged crystallites to a substrate, sintering the arranged crystallites to a substrate, growing epitaxial layers on top of the arranged crystallites, bonding the arranged crystallites, and doping the arranged crystallites.

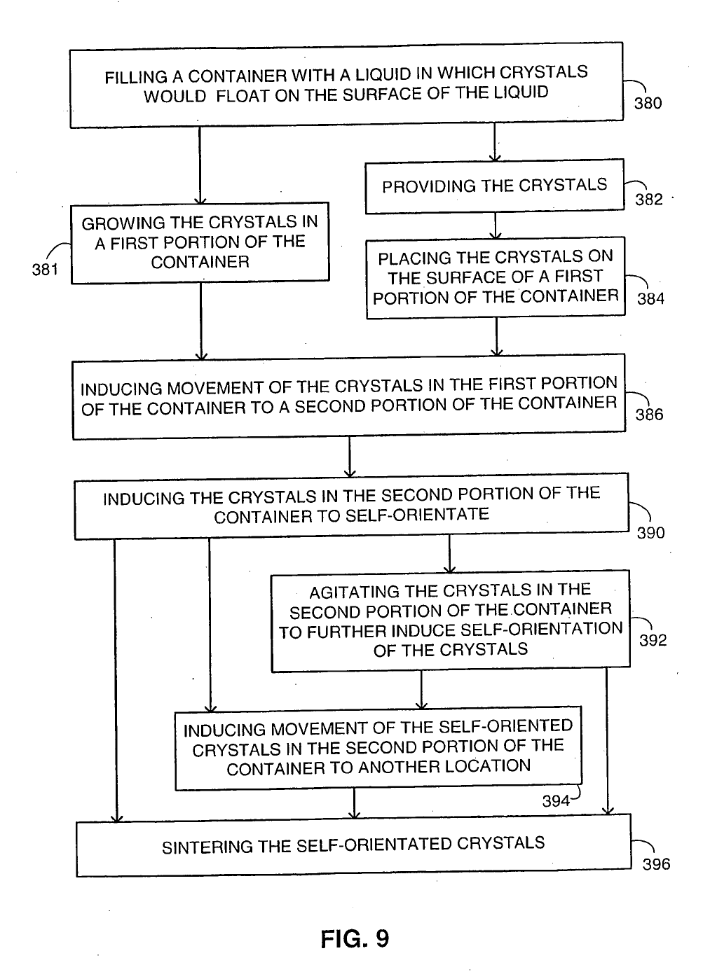

Reference is now made to FIG. 9, which is a schematic illustration of a crystalline sheet formation method, operative in accordance with another embodiment of the disclosed technique. In procedure 380, a container, in which crystallites will be sintered to form a continuous crystalline sheet, is filled with a liquid. The liquid and the crystallites have chemical and physical properties with respect to one another such that at least a portion of the crystallites will float on the surface of the liquid. With reference to FIG. 1, container 102 contains a liquid 108. In general, liquid 108 and crystallites 110 should have physical and chemical properties with respect to one another that enable at least a portion of crystallites 110 to float on the surface of liquid 108, for example through gravitation, surface tension properties, amphiphilic properties and the like.

In procedure 381, the crystallites, which are to be sintered into a continuous crystalline sheet, are grown in a first portion of the container. With reference to FIG. 1, in an embodiment of the disclosed technique, crystallites 110 can be grown in a portion of container 102 from liquid 108, as described above with reference to FIG. 7, where, as an example, group-III metal nitride crystallites are grown from a group-III metal liquid and a nitrogen plasma generating unit.

In procedure 382, the crystallites, which are to be sintered into an oriented continuous crystalline sheet, are provided. For example, the crystallites can be grown in a location other than the container. With reference to FIG. 1, in another embodiment of the disclosed technique, crystallites 110 can be grown in a different location (other than container 102), and physically provided to a portion of container 102, as depicted by arrow 109.

In procedure 384, the crystallites provided in procedure 382 are placed in a first portion of the container. It is noted that procedures 382 and 384 can be executed simultaneously (i.e., providing the crystallites on the surface of the liquid in the container). It is also noted that after procedure 380, the method depicted in FIG. 9 can be executed via either procedure 381, or procedures 382 and 384. With reference to FIG. 1, crystallites 110 are physically provided to a portion of container 102, as depicted by arrow 109.

The method depicted in FIG. 9 is not limited in any way to using a single container, in which all the procedures of the method are performed. The different portions of the container may be completely divided into separate containers, as described with reference to FIG. 1.

In procedure 386, the crystallites in the first portion of the container are induced to move to a second portion of the container. The crystallites can be induced to move by any suitable means, such as by thermally convecting the liquid in the container in a direction pointing from the first portion to the second portion of the container. The crystallites can also be induced to move by circulating the liquid via a pump. The crystallites can furthermore be induced to move by a gravitational stream, thermo-capillarity, magneto-dynamics, mechanical waving, stirring and mixing, and means described in reference to FIG. 1, or any combination thereof. In general, since the conditions (i.e., temperature and pressure) for crystal growth can be very similar to the conditions for sintering, in order to prevent the crystallites from forming a crystalline sheet in the first portion, the crystallites in the first portion are continuously induced to move towards the second portion. Crystalline sheet formation should be prevented in the first portion of the container because crystallites in that portion, either grown or provided, will not be able to properly orientate themselves to form a crystalline sheet having a low density of crystalline sheet defects given the conditions present therein. The rate of the movement of the crystallites is preferably reduced in the second portion of the container. With reference to FIG. 1, flow unit 105 induces crystallites 110, either grown in, or provided to, a portion of container 102, to move away from crystal introduction section 118 towards crystalline sheet formation section 124, through crystal transition section 120. Flow unit 105 induces a flow in liquid 108 which in turn induces crystallites 110 to move.

In procedure 390, the crystallites in the second portion of the container are induced to self-orientate. The crystallites are induced to self-orientate due to the continuous flow of the liquid and the shape of the container. With reference to FIG. 1, in crystal transition section 120, crystallites 110 are induced to flow to another section of container 102, towards crystalline sheet formation section 124. In crystalline sheet formation section 124, the velocity of crystallites 110 is usually reduced in order to allow crystallites 110 to self-orientate.

In procedure 392, the crystallites in the second portion are agitated, either ultrasonically, mechanically or electromagnetically, as described above with reference to FIG. 1, or a combination thereof, to further induce self-orientation of the crystallites. It is noted that procedure 392 is optional, and that the method depicted in FIG. 9 can proceed directly from procedure 390 to procedure 394 (or to procedure 396). With reference to FIG. 1, crystallites 110 can also be assisted in self-orientation by agitation, either ultrasonically, mechanically or magnetically, or a combination thereof. Ultrasonic agitation can be provided by an ultrasound unit (not shown) coupled with crystalline sheet formation section 124 of container 102 which applies ultrasonic waves. Mechanical agitation can be provided by a mechanical unit (i.e., vibrator, not shown), also coupled with crystalline sheet formation section 124 of container 102, which applies mechanical vibrations or waves to the liquid. Electromagnetic agitation can be provided by an electromagnetic unit (i.e., an electromagnetic field generator, not shown), also coupled with crystalline sheet formation section 124 of container 102. The electromagnetic unit can generate a magnetic or electrical alternating induction, which can assist crystallites 110 in self-orientation if crystallites 110 are sensitive to such an induction.

In procedure 394, the self-orientated crystallites in the second portion are induced to move to another location. The other location can be a third portion of the container, or a location located outside the container. It is noted that procedure 394 is optional, and that the method depicted in FIG. 9 can proceed directly from procedure 390, or procedure 392, to procedure 396. With reference to FIG. 1, in another embodiment of the disclosed technique, once crystallites 110 have been self-orientated in crystalline sheet formation section 124, crystallites 110 can be removed from container 102 in crystal removal section 126 via track 114.

In procedure 396, the self-orientated crystallites are sintered to form a uniformly oriented continuous crystalline sheet which should have a low density of crystalline sheet defects. If procedure 394 is executed, then the sintering in procedure 396 is executed in the other location. If procedure 394 is not executed, then the sintering in procedure 396 is executed in the second portion of the container. With reference to FIG. 1, in an embodiment of the disclosed technique, once crystallites 110 have been self-orientated in crystalline sheet formation section 124, heat can be applied to crystallites 110, in crystalline sheet formation section 124, by a heater (not shown), or by creating a deposition environment on crystallites 110, in order to sinter the crystallites. Sintering the crystallites causes crystallites 110 to form a uniformly oriented continuous crystalline sheet. The continuous crystalline sheet can then be removed from container 102, for example, by using a net or a track, and used.

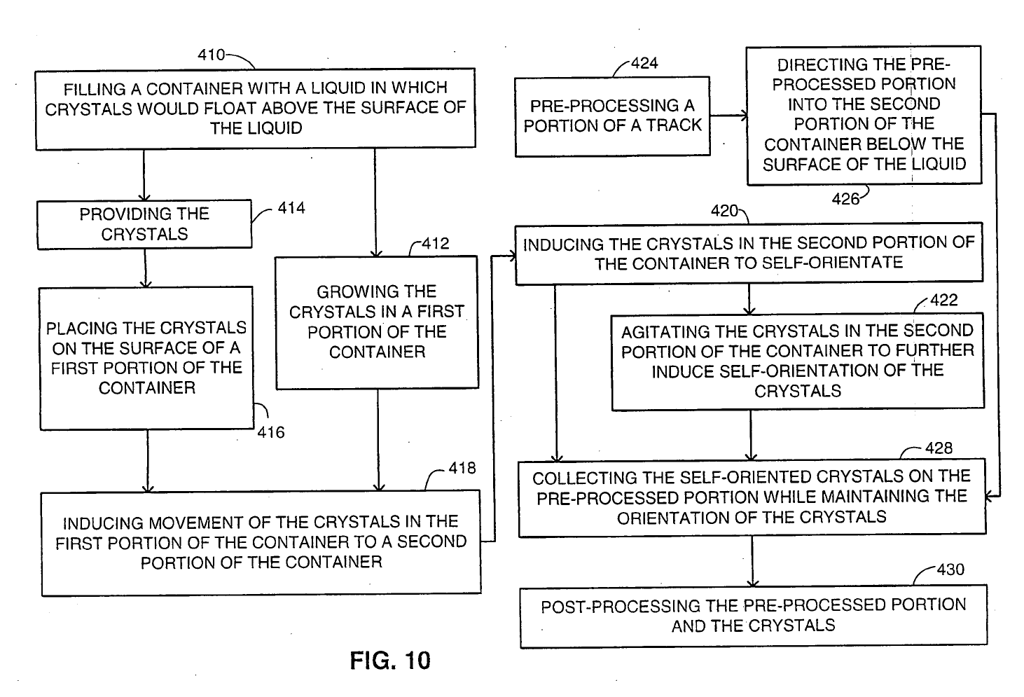

Reference is now made to FIG. 10, which is a schematic illustration of another crystalline sheet formation method, operative in accordance with a further embodiment of the disclosed technique. In procedure 410, a container, in which crystallites will be sintered to form a continuous crystalline sheet, is filled with a liquid. The liquid and the crystallites have chemical and physical properties with respect to one another such that at least a portion of the crystallites will float on the surface of the liquid. With reference to FIG. 1, container 102 contains a liquid 108. In general, liquid 108 and crystallites 110 should have physical and chemical properties with respect to one another that enable at least a portion of crystals 110 to float on the surface of liquid 108, for example, through gravitation, surface tension properties, amphiphilic properties and the like.

In procedure 412, the crystallites, which are to be sintered into a continuous crystalline sheet, are grown in a first portion of the container. With reference to FIG. 1, in an embodiment of the disclosed technique, crystallites 110 can be grown in a portion of container 102 from liquid 108, as described above with reference to FIG. 7, where, as an example, group-III metal nitride crystallites are grown from a group-III metal liquid and a nitrogen plasma generating unit.

In procedure 414, the crystallites, which are to be sintered into a continuous crystalline sheet, are provided. For example, the crystallites can be grown in a location other than the container. With reference to FIG. 1, in another embodiment of the disclosed technique, crystallites 110 can be grown in a different location (other than container 102), and physically provided to a portion of container 102, as depicted by arrow 109.

In procedure 416, the crystallites provided in procedure 414 are placed in a first portion of the container. It is noted that procedures 414 and 416 can be executed simultaneously. It is also noted that after procedure 410, the method depicted in FIG. 10 can be executed via either procedure 412, or procedures 414 and 416. With reference to FIG. 1, crystallites 110 are physically provided to a portion of container 102, as depicted by arrow 109.

The method depicted in FIG. 10 is not limited in any way to using a single container, in which all the procedures of the method are performed. The different portions of the container may be completely divided into separate containers, as described with reference to FIG. 1.

In procedure 418, the crystallites in the first portion of the container are induced to move to a second portion of the container. The crystallites can be induced to move by thermally convecting the liquid in the container in a direction pointing from the first portion to the second portion of the container. The crystallites can also be induced to move by inducing a flow in the liquid. The crystallites can furthermore be induced to move by a gravitational stream, thermo-capillarity, magneto-dynamics, mechanical waving, propelling, or stirring and mixing, as mentioned above in reference to FIG. 1, or any combination thereof. In general, since the conditions (i.e., temperature and pressure) for crystal growth can be very similar to the conditions for crystalline sheet formation, in order to prevent the crystallites from forming a crystalline sheet, the crystallites in the first portion are continuously induced to move towards the second portion. Crystalline sheet formation should be prevented in the first portion of the container because crystallites in that portion, either grown or provided, will not be able to properly orientate themselves to form a crystalline sheet having a low density of crystalline sheet defects given the conditions present therein. In procedure 418, the crystallites are induced to flow, and advance, preferably slowly, from the first portion of the container to the second portion of the container. The rate of movement of the crystallites is thus reduced in the second portion of the container. With reference to FIG. 1, flow unit 105 induces crystallites 110, either grown in, or provided to, a portion of container 102, to move away from crystal introduction section 118 towards crystalline sheet formation section 124. Flow unit 105 induces a flow in liquid 108 which in turn induces crystallites 110 to move.

In procedure 420, the crystallites in the second portion of the container are induced to self-orientate. The crystallites are induced to self-orientate due to the continuous flow of the liquid and the shape of the container. With reference to FIG. 1, crystallites 110 are induced to flow to another section of container 102, towards crystalline sheet formation section 124, in which the velocity of crystallites 110 is reduced in order to allow crystallites 110 to self-orientate.

In procedure 422, the crystallites in the second portion are agitated, either ultrasonically, mechanically or magnetically, as described above in reference to FIG. 1, or a combination thereof, to further induce self-orientation of the crystallites. It is noted that procedure 422 is optional, and that the method depicted in FIG. 10 can proceed directly from procedure 420 to procedure 428. With reference to FIG. 1, crystallites 110 can also be assisted in self-orientation by agitation, either ultrasonically, mechanically or magnetically, as described above in reference to FIG. 1, or a combination thereof. Ultrasonic agitation can be provided by an ultrasound unit (not shown) coupled with crystalline sheet formation section 124 of container 102 which applies ultrasonic waves. Mechanical agitation can be provided by a mechanical unit (not shown), also coupled with crystalline sheet formation section 124 of container 102, which applies mechanical vibrations or waves to the liquid. Electromagnetic agitation can be provided by an electromagnetic unit (not shown), also coupled with crystalline sheet formation section 124 of container 102. The electromagnetic unit can generate a magnetic or electrical alternating induction, which can assist crystallites 110 in self-orientation, if crystallites 110 are sensitive to such an induction.

In procedure 424, a portion of a track is pre-processed. The track can be considered a substrate, or a surface, which can be clad with the crystallites, or can collect the crystallites. The pre-processing may include, for example, sputtering the track with a particular chemical element or molecule, altering the temperature of the track, indenting the track at predetermined space intervals, and the like. With reference to FIG. 1, track 114 can be made of stainless steel, tantalum, molybdenum, steel, aluminum, copper alloys, plastic, graphite fabric, or any other suitable material on which crystallites 110 will be deposited or collected. Track 114 is provided to pre-processing unit 104, in the direction of arrow 116. Pre-processing may include, for example, sputtering track 114 with a particular chemical element or molecule, altering the temperature of track 114, indenting track 114 at predetermined space intervals, and the like.

In procedure 426, the pre-processed portion of the track is directed into the second portion of the container below the surface of the liquid. It is noted that procedures 424 and 426 can be executed at the same time as procedures 410 to 422 are executed. With reference to FIG. 1, rollers 122_{A} and 122_{B} guide track 114 from pre-processing unit 104 into container 102. Roller 122_{C} guides track 114 into liquid 108, underneath crystallites 110 and out of container 102.

In procedure 428, the self-orientated crystallites are collected onto the pre-processed portion of the track in the second portion of the container, which is removed from the liquid at a gradual slope, thereby maintaining the orientation of the crystallites. The track generally proceeds at a rate compatible with the flow rate of the crystallites (which is slower than their flow rate before they reach the track), thereby allowing the crystallites to be collected onto (or to “climb” onto) the track. The angle formed between the track and the surface of the liquid is selected such that the slope of the track is gradual when the crystallites are removed from the liquid. A gradual slope ensures that the crystallites will not lose their orientation as they are removed from the liquid and that they will not slip off of the track back into the container. With reference to FIG. 1, in crystal removal section 126, rollers 122_{B}, 122_{C} and 122_{D} guide track 114 underneath crystallites 110. Track 114 generally proceeds at a rate compatible with the flow rate of crystallites 110 (which is slower than their flow rate before they reach track 114), thereby allowing crystallites 110 to be collected onto (or to “climb” onto) track 114. In crystal removal section 126, rollers 122_{B}, 122_{C} and 122_{D} guide track 114 underneath crystallites 110. The angle formed between track 114 and the surface of liquid 108 in FIG. 1 is depicted by angle 121. Angle 121 is selected such that the slope of track 114 is gradual when crystallites 110 are removed from liquid 108. A gradual slope ensures that the tiled surface of crystallites 110 will not lose its orientation as it is removed from liquid 108 and that crystallites 110 will not slip off of track 114 back into container 102.

In procedure 430, either the pre-processed portion of the track, the crystallites, or both, are post-processed. The post-processing can include sintering the crystallites (thereby sintering them into a uniformly oriented continuous crystalline sheet), sectioning the track, and the like. With reference to FIG. 1, roller 122_{D} guides track 114 towards post-processing unit 106. Crystallites 110 on track 114 are provided to post-processing unit 106, which post-processes either crystallites 110, track 114 or both.

It is noted that the procedures of the method depicted in FIG. 10 which concern the track, can be further applied to the method depicted in FIG. 8. For example, removing of the uniformly oriented crystalline sheet, mentioned with reference to FIG. 8, from the liquid, can be performed using a track, of which a portion can optionally be pre-processed.

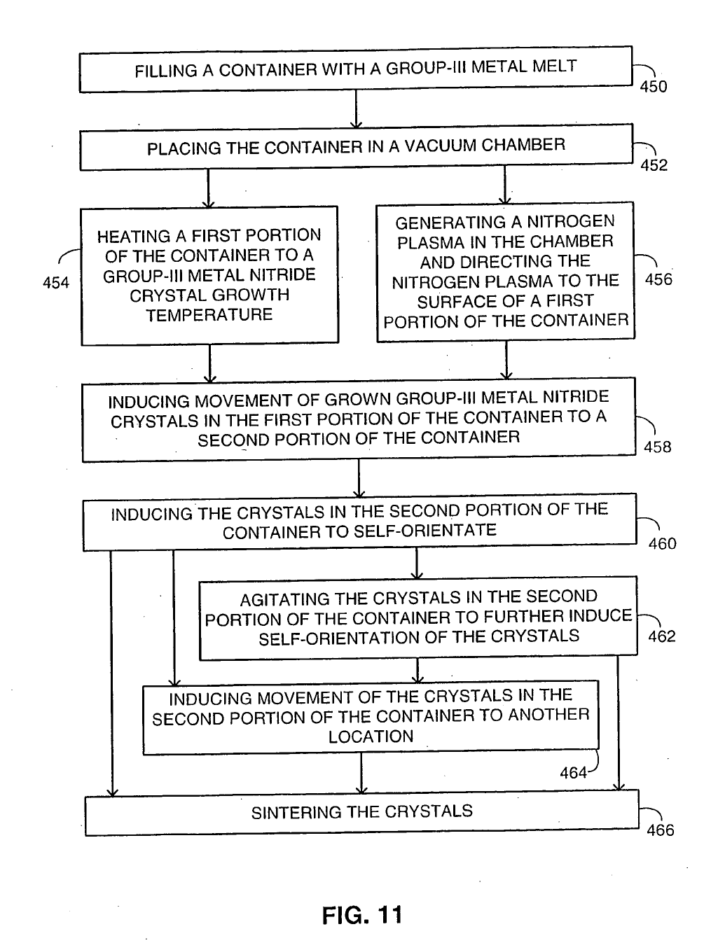

Reference is now made to FIG. 11, which is a schematic illustration of a group-III metal nitride crystalline sheet formation method, operative in accordance with another embodiment of the disclosed technique. In procedure 450, a container is filled with a group-III metal melt, for example a gallium melt. In general, in order to retain a group-III metal melt in a liquid phase, the temperature, or the pressure, or both, of the surroundings need to be altered from standard ambient temperature (25° C.) and pressure (100 KPa). For example, the temperature of the container may be increased. With reference to FIG. 7, container 312 contains a gallium melt 318.

In procedure 452, the container is placed in a vacuum chamber, in order to alter the pressure conditions in which the group-III metal melt is located. The pressure in the vacuum chamber is reduced to a predetermined sub-atmospheric pressure. For example, if a gallium melt is used, the pressure in the vacuum chamber is reduced to 10⁻³ Pa. With reference to FIG. 7, container 312, pump 344, intake pipe 341, outtake pipe 343, heater 360, nitrogen plasma generating unit 350, a section of track 324 and rollers 334_{A}, 334_{B}, 334_{C} and 334_{D} are all located inside vacuum chamber 354. The pressure of vacuum chamber 354 is reduced by vacuum pump 356 to sub-atmospheric pressures, for example, to 10⁻³ Pa.

In procedure 454, a first portion of the container is heated to a group-III metal nitride crystal growth temperature. For example, if a gallium melt is used, then a first portion of the container is heated to approximately 750°-950° C., which is the growth temperature for GaN crystallites. With reference to FIG. 7, heater 360 applies heat (depicted by arrows 362) to the portion of gallium melt 318 located in crystal growth section 327. When the temperature of gallium melt 318 reaches approximately 750° C., GaN crystallites 320 will begin to form on the surface of gallium melt 318, as gallium and nitrogen react to form GaN crystallites at this temperature.

In procedure 456, a nitrogen plasma is generated in the vacuum chamber and is directed to the surface of the first portion of the container mentioned in procedure 454. It is noted that the nitrogen plasma generated contains no electrodes. For example, if a gallium melt is used, then at 750°-950° C., the nitrogen plasma will react with the gallium melt to form GaN crystallites. Due to the chemical and physical properties of gallium with respect to those of GaN, GaN crystallites will float on the surface of the gallium melt. It is noted that procedures 454 and 456 can be executed simultaneously. With reference to FIG. 7, in crystal growth section 327, nitrogen plasma generating unit 350 directs a nitrogen plasma (depicted by arrows 352) towards the surface of gallium melt 318. It is noted that the nitrogen plasma generated by nitrogen plasma generating unit 350 contains no electrodes.

The method depicted in FIG. 11 is not limited in any way to using a single container, in which the procedures of the method are performed. The different portions of the container may be completely divided into separate containers, as described with reference to FIG. 1.

In procedure 458, the grown group-III metal nitride crystallites are induced to move from the first portion of the container to a second portion of the container in order to prevent the crystallites from sintering and forming a continuous crystalline sheet. For example, if a gallium melt is used, then at the temperature and pressure conditions in procedures 454 and 456 (i.e., 10⁻³ Pa and 750° C.), grown GaN crystallites can sinter to form a continuous GaN crystalline sheet, if the GaN crystallites are not moved out of that portion within an adequate amount of time. In general, a GaN crystalline sheet formed in that portion will have a high density of crystalline sheet defects, because the GaN crystallites (of which it is formed) will not have sufficient time to properly self-orientate before sintering together to form a continuous GaN crystalline sheet. The crystallites are thus induced to move by thermally convecting the group-III metal melt in a direction pointing from the first portion to the second portion of the container. The crystallites can also be induced to move by circulating the metal melt via a pump or other means mentioned in reference to FIG. 1. In procedure 458, the group-III metal nitride crystallites are preferably induced to advance slowly to the second portion of the container. The rate of the movement of the crystallites is thus reduced in the second portion of the container. The temperature conditions in the first portion of the container are such that the group-III metal nitride crystallites will not sinter to form a continuous crystalline sheet. With reference to FIG. 7, in order to prevent GaN crystallites 320 from sintering into a continuous GaN crystalline sheet in crystal growth section 327, a flow is induced in gallium melt 318, in the direction of an arrow 322. The induced flow in gallium melt 318 in turn induces GaN crystallites 320 to move. This induced flow causes GaN crystallites 320 to move away from crystal growth section 327 towards crystalline sheet formation section 330. The flow is induced by heater 360 and pump 344. The conditions in crystal growth section 327 are controlled such that GaN crystallites 320 will be prevented from sintering to form a continuous GaN crystalline sheet.

In procedure 460, the group-III metal nitride crystallites in the second portion of the container are induced to self-orientate. The crystallites are induced to self-orientate due to the continuous flow of the group-III metal melt and due to the shape of the container. With reference to FIG. 7, in crystalline sheet formation section 330, GaN crystallites 320 are allowed to self-orientate.

In procedure 462, the group-III metal nitride crystallites in the second portion of the container are agitated, either ultrasonically, mechanically, magnetically, or by any other means mentioned with respect to FIG. 7, or a combination thereof, in order to further induce the group-III metal nitride crystallites to self-orientate. It is noted that procedure 462 is optional, and that the method depicted in FIG. 11 can proceed directly from procedure 460 to procedure 464. With reference to FIG. 7, GaN crystallites 320 can also be assisted in self-orientation by agitation, either ultrasonically, mechanically, magnetically, a combination thereof, or otherwise as described with reference to FIG. 1. Ultrasonic agitation can be provided by an ultrasound unit (not shown) coupled with crystalline sheet formation section 330 of container 312 which applies ultrasonic waves. Mechanical agitation can be provided by a mechanical unit (not shown), also coupled with crystalline sheet formation section 330 of container 312 which applies mechanical vibrations or waves to the liquid. Electromagnetic agitation can be provided by an electromagnetic unit (not shown), also coupled with crystalline sheet formation section 124 of container 102. The electromagnetic unit can generate a magnetic or electrical alternating induction, which can assist crystallites 110 in self-orientation, if crystallites 110 are sensitive to such an induction.

In procedure 464, the self-orientated group-III metal nitride crystallites in the second portion of the container are induced to move to another location. The other location can be a third portion of the container, or a location located outside the container. It is noted that procedure 464 is optional and that the method depicted in FIG. 11 can proceed directly from procedure 460 or procedure 462 to procedure 466. With reference to FIG. 7, in another embodiment of the disclosed technique, once GaN crystallites 320 have been self-orientated in crystalline sheet formation section 330, GaN crystallites 320 can be removed from container 312 in crystal removal section 332, via track 324.

In procedure 466, the group-III metal nitride crystallites are sintered to form a group-III metal nitride crystalline sheet. Since the group-III metal nitride crystallites were first allowed to self-orientate themselves in conditions that do not allow the crystallites to sinter and form a continuous crystalline sheet, then when the crystallites are sintered, the continuous crystalline sheet should have a low density of crystalline sheet defects. If procedure 464 is executed, then the sintering will be executed in the other location. If procedure 464 is not executed, then the sintering will be executed in the second portion of the container. With reference to FIG. 7, in an embodiment of the disclosed technique, once GaN crystallites 320 have been self-orientated in crystalline sheet formation section 330, heat can be applied to GaN crystallites 320, in crystalline sheet formation section 330, by a heater (not shown), in order to sinter the GaN crystallites, thereby causing GaN crystallites 320 to form a continuous GaN crystalline sheet.

According to one embodiment of the disclosed technique, a pressure of 2×10⁻⁴ Pa is attained in the surroundings of the container (a “crucible”), containing the liquid gallium. The liquid gallium is then heated to a temperature of 750° C., followed by the application of an argon magnetron inductive plasma at a pressure of 30 Pa, and an application of a −4.5 kV (kilovolt) AC bias current on the liquid gallium. The biasing of the heated depressurized liquid gallium, to which the argon magnetron plasma was applied, sputters and cleans the liquid gallium surface. The biasing of the gallium is then halted and the application of the argon plasma is stopped. A nitrogen plasma is then applied, at a nitrogen pressure of 5 Pa. The temperature of the liquid gallium is then raised to 850° C., and the biasing of the gallium is resumed once again. After a period of about 30 seconds, the surface tension of the liquid gallium changes, and the natural convex meniscus of the liquid gallium is transformed into a concave wetting angle (i.e., the angle formed between the liquid surface and the container walls). Immediately thereafter, the gallium liquid surface is covered with a GaN crystalline layer. The nitrogen pressure is varied between 3-30 Pa, while the optimal pressure for attaining the highest nitrogen ion current is approximately 13 Pa. Different kinds of materials can be used for the crucible, for example, fused quartz, graphite, boron nitride and corundum. The process is completed after a period of about 10 minutes, and is followed by cooling of the crucible and removing the GaN which was formed.

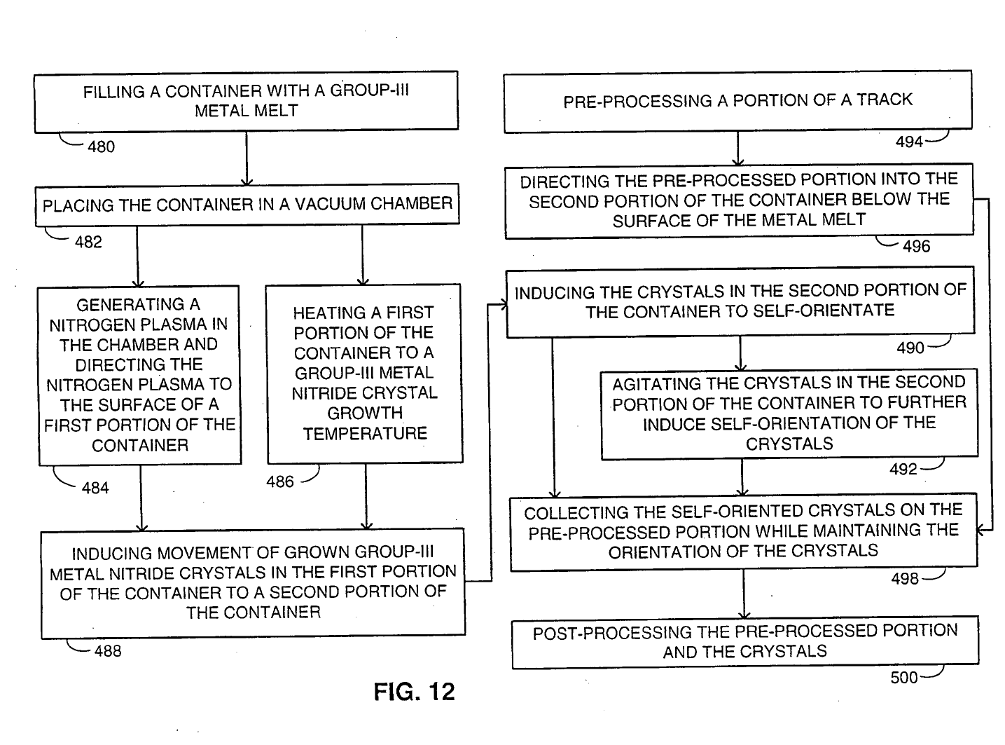

Reference is now made to FIG. 12, which is a schematic illustration of another group-III metal nitride crystalline sheet formation method, operative in accordance with a further embodiment of the disclosed technique. In procedure 480, a container is filled with a group-III metal melt, for example a gallium melt. In general, in order to retain a group-III metal melt in a liquid phase, the temperature, or the pressure, or both, of the surroundings need to be altered from standard ambient temperature (25° C.) and pressure (100 KPa). For example, the temperature of the container may be increased to 30° C. With reference to FIG. 7, container 312 contains a gallium melt 318.

In procedure 482, the container is placed in a vacuum chamber, in order to alter the pressure conditions in which the group-III metal melt is located. It is noted that the vacuum chamber is built in a manner that the track mentioned in procedures 494 and 496 can enter and exit the vacuum chamber without having the pressure of the vacuum chamber altered, or can alternatively be split between a track portion within the vacuum chamber and a track portion external to the vacuum chamber. The pressure in the vacuum chamber is reduced to a predetermined sub-atmospheric pressure. For example, if a gallium melt and a nitrogen plasma are used, the pressure in the vacuum chamber is reduced to 10⁻³ Pa. With reference to FIG. 7, container 312, pump 344, intake pipe 341, outtake pipe 343, heater 360, nitrogen plasma generating unit 350, a section of track 324 and rollers 334_{A}, 334_{B}, 334_{C} and 334_{D} are located inside vacuum chamber 354. The pressure inside vacuum chamber 354 is reduced by vacuum pump 356 to sub-atmospheric pressures, for example, 10⁻³ Pa.

In procedure 484, a nitrogen plasma is generated in the vacuum chamber and is directed to the surface of a first portion of the container. It is noted that the nitrogen plasma generated contains no electrodes. For example, if a gallium melt is used, then at 750° C., the nitrogen plasma will react with the gallium melt to form GaN crystallites. Due to the chemical and physical properties of gallium with respect to those of GaN, GaN crystallites will float on the surface of the gallium melt. With reference to FIG. 7, in crystal growth section 327, nitrogen plasma generating unit 350 directs a nitrogen plasma (depicted by arrows 352) towards the surface of gallium melt 318. It is noted that the nitrogen plasma generated by nitrogen plasma generating unit 350 contains no electrodes.

In procedure 486, the first portion of the container mentioned in procedure 490 is heated to a group-III metal nitride crystal growth temperature. For example, if a gallium melt is used, then a first portion of the container is heated to approximately 750° C., which is the growth temperature for GaN crystallites. It is noted that procedures 484 and 486 can be executed simultaneously. With reference to FIG. 7, heater 360 applies heat (depicted by arrows 362) to the portion of gallium melt 318 located in crystal growth section 327. When the temperature of gallium melt 318 reaches approximately 750° C., GaN crystallites 320 will begin to form on the surface of gallium melt 318, as gallium and nitrogen react to form GaN crystallites at this temperature.

The method depicted in FIG. 12 is not limited in any way to using a single container, in which all the procedures of the method are performed. The different portions of the container may be completely divided into separate containers, as described with reference to FIG. 1.

In procedure 488, the grown group-III metal nitride crystallites are induced to move from the first portion of the container to a second portion of the container in order to prevent the crystallites from sintering and forming a continuous crystalline sheet in the first portion of the container. For example, if a gallium melt is used, then at the temperature and pressure conditions in procedures 484 and 486 (i.e., 10⁻³ Pa and 750° C.), grown GaN crystallites can sinter to form a continuous GaN crystalline sheet, if the GaN crystallites are not moved out of that portion within an adequate amount of time. In general, a GaN crystalline sheet formed in that portion will have a high density of crystalline sheet defects, because the GaN crystallites (of which it is formed) will not have sufficient time to properly self-orientate before sintering together to form a continuous GaN crystalline sheet. The crystallites are thus induced to move by thermally convecting the group-III metal melt in a direction pointing from the first portion to the second portion of the container. The crystallites can also be induced to move by circulating the metal melt via a pump or other suitable means. Preferably, the group-III metal nitride crystallites are induced to advance slowly to the second portion of the container. The rate of the movement of the crystallites is thus reduced in the second portion of the container. The conditions in the first portion of the container are such that the group-III metal nitride crystallites will not sinter to form a continuous crystalline sheet. With reference to FIG. 7, in order to prevent GaN crystallites 320 from sintering into a continuous GaN crystalline sheet, a flow is induced in gallium melt 318, in the direction of an arrow 322. The induced flow in gallium melt 318 in turn induces GaN crystallites 320 to be in a constant state of perturbation which prevents sintering. This induced flow also causes GaN crystallites 320 to move away from crystal growth section 327 towards crystalline sheet formation section 330. The flow is induced by heater 360 and pump 344. The conditions in crystal growth section 327 are controlled such that GaN crystallites 320 will be prevented from sintering to form a continuous GaN crystalline sheet.

In procedure 490, the group-III metal nitride crystallites in the second portion of the container are induced to self-orientate. The crystallites are induced to self-orientate due to the continuous flow of the group-III metal melt and the shape of the container. With reference to FIG. 7, in crystalline sheet formation section 330, GaN crystallites 320 are allowed to self-orientate.

In procedure 492, the crystallites in the second portion of the container are agitated, either ultrasonically, mechanically, magnetically, or otherwise by the means mentioned in reference of FIG. 1, or a combination thereof, in order to further induce the crystallites to self-orientate. It is noted that procedure 492 is optional and that the method depicted in FIG. 12 can proceed directly from procedure 490 to procedure 498. With reference to FIG. 7, GaN crystallites 320 can also be assisted in self-orientation by agitation, either ultrasonically, mechanically, magnetically or otherwise by means mentioned in reference to FIG. 1, or a combination thereof. Ultrasonic agitation can be provided by an ultrasound unit (not shown) coupled with crystalline sheet formation section 330 of container 312 which applies ultrasonic waves. Mechanical agitation can be provided by a mechanical unit (not shown), also coupled with crystalline sheet formation section 330 of container 312 which applies mechanical vibrations or waves to the liquid. Electromagnetic agitation can be provided by an electromagnetic unit (not shown), also coupled with crystalline sheet formation section 124 of container 102. The electromagnetic unit can generate a magnetic or electrical alternating induction, which can assist crystallites 110 in self-orientation, if crystallites 110 are sensitive to such an induction.

In procedure 494, a portion of a track is pre-processed. The track can be considered a substrate, or a surface, on which the crystallites will be deposited on. The track can be made of a conducting, a semi-conducting, or a dielectric material. The track can be, for example, a stainless steel track. The pre-processing may include, for example, perforating the track, cleaning the track using wet chemicals, drying the track, applying an argon plasma on the track for physical cleaning, sputtering the track with group-III metal nitride crystallites, altering the temperature of the track, indenting the track at predetermined space intervals, and the like. With reference to FIG. 7, track 324 can be made of a conducting, a semi-conducting, or a dielectric material. For example, track 324 can be made of stainless steel. Pre-processing unit 314 pre-processes track 324. Pre-processing may include, for example, perforating track 324, cleaning track 324 using wet chemicals, drying track 324, applying an argon plasma on track 324 for physical cleaning, sputtering track 324 with a GaN amorphous layer, altering the temperature of track 324, indenting track 324 at predetermined space intervals, and the like.

In procedure 496, the pre-processed portion of the track is directed into the second portion of the container below the surface of the liquid. With reference to FIG. 7, rollers 334_{A} and 334_{B} guide track 324 from pre-processing unit 314 into container 312. Roller 334_{C} guides track 324 into gallium melt 318, underneath GaN crystallites 320 and out of container 312.

In procedure 498, the self-orientated crystallites are collected onto the pre-processed portion of the track, mentioned in procedure 496, in the second portion of the container, which is removed from the liquid at a gradual slope, thereby maintaining the orientation of the crystallites. It is noted that procedures 482 to 492 can be executed simultaneously as procedure 496 is executed. The flow induced in the liquid in procedure 488 induces the crystallites to move onto the track. The angle formed between the track and the surface of the liquid is selected such that the slope of the track is gradual when the crystallites are removed from the liquid. A gradual slope ensures that the crystallites will not lose their orientation as they are removed from the liquid and that they will not slip off of the track back into the container. With reference to FIG. 7, once GaN crystallites 320 have been self-orientated in crystalline sheet formation section 330, GaN crystallites 320 can be removed from container 312 in crystal removal section 332, via track 324. In crystal removal section 332, rollers 334₂, 334₃ and 334₄ guide track 324 underneath GaN crystallites 320, and move GaN crystallites 320 from crystalline sheet formation section 330 to crystal removal section 332. Track 324 generally proceeds at a rate slower than the flow rate of GaN crystallites 320, thereby allowing GaN crystallites 320 to be collected onto track 324. The angle formed between track 324 and the surface of gallium melt 318 is depicted by angle 336. Angle 336 is selected such that the slope of track 324 is gradual when GaN crystallites 320 are removed from gallium melt 318.

In procedure 500, either the pre-processed portion of the track, the crystallites, or both, are post-processed. The post-processing can include sintering the group-III metal nitride crystallites (thereby sintering them into a continuous group-III metal nitride crystalline sheet), sectioning the track, and the like. With reference to FIG. 7 roller 334_{D} guides track 324 towards post-processing unit 316. GaN crystallites 320 on track 324 are provided to post-processing unit 316, which post-processes either GaN crystallites 320, track 324 or both.

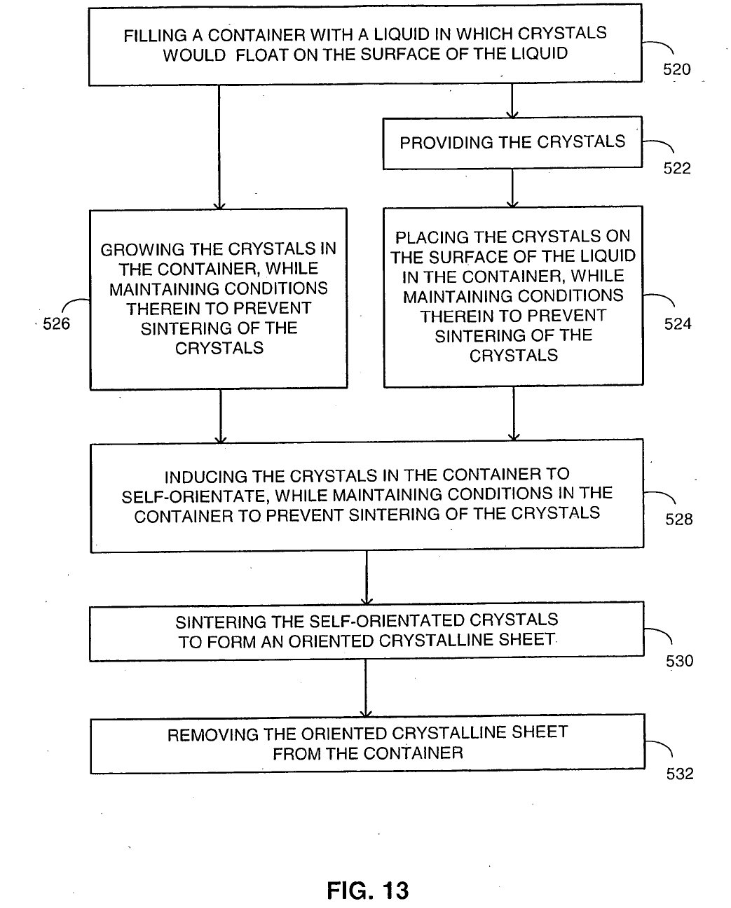

Reference is now made to FIG. 13, which is a schematic illustration of a crystalline sheet formation method, operative in accordance with another embodiment of the disclosed technique. In procedure 520, a container, in which crystallites will be sintered to form a crystalline sheet, is filled with a liquid. The liquid and the crystallites have chemical and physical properties with respect to one another to enable at least a portion of the crystallites to float on the surface of the liquid, for example through gravitation, surface tension properties, amphiphilic properties and the like.

In procedure 526, the crystallites, which are to be sintered into a crystalline sheet, are grown in the container while maintaining conditions therein to prevent sintering of the crystallites. For example, as described above with reference to FIG. 7, group-III metal nitride crystallites are grown from a group-III metal liquid and a nitrogen plasma generating unit. In general, since the conditions (i.e., temperature and pressure) for crystal growth can be very similar to the conditions for sintering, in order to prevent the crystallites from sintering, the conditions in the container during procedure 526 are maintained such that no sintering will occur (i.e., allowing the crystallites to be spaced apart from each other and applying a specific temperature in the container). Crystalline sheet formation should be prevented during procedure 526 because the crystallites will not be able to properly orientate themselves to form a uniformly oriented crystalline sheet having a low density of crystalline sheet defects, especially if the conditions present therein for crystal growth are very similar to crystal sintering conditions.

In procedure 522, the crystallites, which are to be sintered into a crystalline sheet, are provided. For example, the crystallites can be grown in a location other than the container, and physically provided to the container.

In procedure 524, the crystallites provided in procedure 522 are placed on the surface of the liquid in the container while maintaining conditions therein to prevent sintering of the crystallites. Again, since the conditions (i.e., temperature and pressure) for crystal growth can be very similar to the conditions for sintering, in order to prevent the crystallites from forming a crystalline sheet, the conditions in the container during procedure 524 are maintained such that no sintering will occur. Crystalline sheet formation should be prevented during procedure 524 because the crystallites will not be able to properly orientate themselves to form a uniformly oriented crystalline sheet having a low density of crystalline sheet defects, given the conditions present therein. It is noted that procedures 522 and 524 can be executed simultaneously (i.e., providing the crystallites on the surface of the liquid in the container). It is also noted that after procedure 520, the method depicted in FIG. 13 can be executed either via procedure 526, or via procedures 522 and 524.

In procedure 528, the crystallites in the container are induced to self-orientate while maintaining conditions therein to prevent sintering of the crystallites. Crystalline sheet formation should be prevented during procedure 528 because until they complete their self-orientation, the crystallites are not ready to form a uniformly oriented crystalline sheet having a low density of sheet defects. This is true especially if the conditions present therein are very similar to crystal sintering conditions. The crystallites are induced to self-orientate by agitation, either ultrasonically, mechanically, magnetically, or by other means described above with reference to FIG. 1, or a combination thereof.

Since the conditions during procedure 526 are suitable for crystal growth, if they are maintained beyond a certain period of time, then sintering between the crystallites can occur spontaneously and spoil the possibility of forming a uniformly oriented crystalline sheet. Therefore, in such cases the conditions during procedure 526 can be maintained for a shortened period of time which is sufficient for growing crystallites but insufficient for sintering. For example, the temperature can be reduced after such a shortened period of time. Alternatively, sintering may be prevented by continuously inducing movement of the crystallites, thereby preventing close contact between the crystallites, which is essential for sintering, yet having no effect on crystal growth. To this end, the crystallites can be induced to move by any means including mechanical waving, stirring or mixing, and even agitation (using intensities and frequencies that will disrupt sintering rather than help self-orientation).

Procedure 528 commences as the conditions in the container are altered so as to prevent sintering. The crystallites in the container are then induced to self-orientate while maintaining conditions therein to prevent sintering of the crystallites. At the end of procedure 528, the crystallites are self-orientated in a compact configuration, such that the edges of each crystal are parallel and adjacent to one another, and the crystallites may be considered as forming a uniformly oriented mosaic-like tiled surface.

In procedure 530, the self-orientated crystallites are sintered to form a uniformly oriented continuous crystalline sheet having a low density of sheet defects, such as misorientations and grain boundaries. Sintering of the crystallites is performed, for example, by heating the crystallites on the surface of the liquid, by applying ultrasonic agitation, or a combination thereof, as described with reference to FIG. 1.

In procedure 532, the sintered oriented crystalline sheet is removed from the container, for example by using a net, a track, or tweezers. After removal of the crystalline sheet from the container, the sheet can be used.

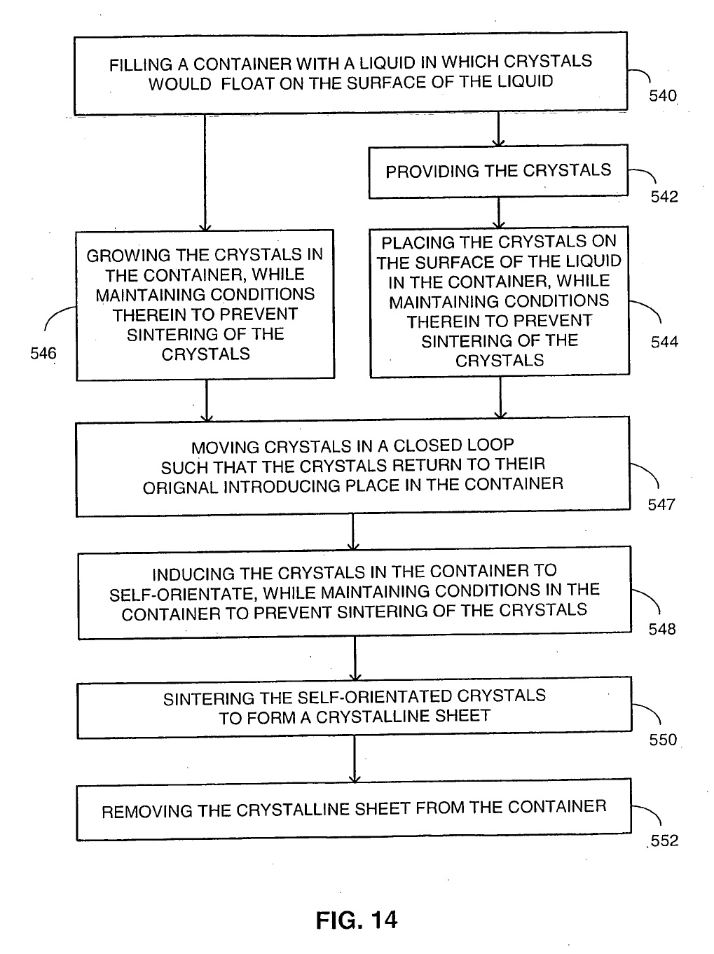

Reference is now made to FIG. 14, which is a schematic illustration of a crystalline sheet formation method, operative in accordance with a further embodiment of the disclosed technique. In procedure 540, a container, in which crystallites will be sintered to form a crystalline sheet, is filled with a liquid. The liquid and the crystallites have chemical and physical properties with respect to one another to enable at least a portion of the crystallites to float on the surface of the liquid, for example through gravitation, surface tension properties, amphiphilic properties and the like.

In procedure 546, the crystallites, which are to be sintered into a crystalline sheet, are grown in the container while maintaining conditions therein to prevent sintering of the crystallites. For example, as described above with reference to FIG. 7, group-III metal nitride crystallites are grown from a group-III metal liquid and a nitrogen plasma generating unit. In general, since the conditions (i.e., temperature and pressure) for crystal growth can be very similar to the conditions for sintering, in order to prevent the crystallites from forming a crystalline sheet, the conditions in the container during procedure 546 are maintained such that no sintering will occurs. Crystalline sheet formation should be prevented during procedure 546 because the crystallites will not be able to properly orientate themselves to form a uniformly oriented crystalline sheet having a low density of crystalline sheet defects, especially if the conditions present therein for crystal growth are very similar to crystal sintering conditions.

In procedure 542, the crystallites, which are to be sintered into a crystalline sheet, are provided. For example, the crystallites can be grown in a location other than the container, and physically provided to the container.

In procedure 544, the crystallites provided in procedure 542 are placed on the surface of the liquid in the container while maintaining conditions therein to prevent sintering of the crystallites. Again, since the conditions (i.e., temperature and pressure) for crystal growth can be very similar to the conditions for sintering, in order to prevent the crystallites from forming a crystalline sheet, the conditions in the container during procedure 544 are maintained such that no sintering will occur. Crystalline sheet formation should be prevented during procedure 544 because the crystallites will not be able to properly orientate themselves to form a crystalline sheet having a low density of crystalline sheet defects, given the conditions present therein. It is noted that procedures 542 and 544 can be executed simultaneously (i.e., providing the crystallites on the surface of the liquid in the container). It is also noted that after procedure 540, the method depicted in FIG. 14 can be executed via either procedure 546, or procedures 542 and 544.

Since the conditions during procedure 546 are suitable for crystal growth, if they are maintained beyond a certain period of time, then sintering between the crystallites can occur spontaneously and spoil the possibility of forming a uniformly oriented crystalline sheet. Therefore, in such cases the conditions during procedure 546 can be maintained for a shortened period of time sufficient for growing crystallites but insufficient for sintering. For example, the temperature is reduced after such a shortened period of time. Alternatively, sintering may be prevented by continuously inducing movement of the crystallites, thereby preventing close contact between the crystallites, which is essential for sintering, yet having no effect on crystal growth. To this end, the crystallites can be induced to move by any means including, mechanical waving, stirring or mixing, and even agitation (using intensities and frequencies that will disrupt sintering rather than help self-orientation).

In procedure 547, the crystallites are moved in a closed loop away from their introduction place in the container, such that at the end of the closed loop, they return to their original introduction place. Moving the crystallites along the closed loop may be performed in various manners. For example, if the container is of annular shape and a flow is induced along the container, the crystallites are moved in a closed loop along the container. In this case, once the crystallites return to their original introduction place, the flow induced in the liquid is stopped.

Alternatively, if the crystallites have electromagnetic properties, a magnetic field may be induced vertically along the liquid in the container for a predetermined amount of time. In this manner, the crystallites are forced to sink in the liquid (or rise above the surface of the liquid). Once the magnetic field is turned off, the crystallites would float (or descend) back to the surface of the liquid, thereby returning to their original introduction place in the container. The manners of moving the crystallites in a closed loop provided herein are merely examples, and in no way limit the manner of performing procedure 547 to the described examples.

In procedure 548, the crystallites in the container are induced to self-orientate while maintaining conditions therein to prevent sintering of the crystallites. Procedure 548 commences as the conditions in the container are altered so as to prevent sintering. Crystalline sheet formation should be prevented during procedure 548 because the crystallites will not be able to properly orientate themselves to form a uniformly oriented crystalline sheet having a low density of crystalline sheet defects, if the conditions present therein are very similar to crystal sintering conditions. The crystallites are induced to self-orientate by agitation, either ultrasonically, mechanically or magnetically, as described above with reference to FIG. 1, or a combination thereof. Ultrasonic agitation can be provided by an ultrasound unit coupled with the container which applies ultrasonic waves. Mechanical agitation can be provided by a mechanical unit, also coupled with the container, which applies mechanical vibrations or waves to the liquid. Electromagnetic agitation can be provided by an electromagnetic unit, also coupled with the container. The electromagnetic unit can generate a magnetic or electrical alternating induction, if the crystallites are sensitive to such an induction. At the end of procedure 548, the crystallites are self-orientated in a compact configuration, such that the edges of each crystallite are parallel and adjacent to one another, and the crystallites may be considered as forming a uniformly oriented mosaic-like tiled surface.

In procedure 550, the self-orientated crystallites are sintered to form a uniformly oriented continuous crystalline sheet which should have a low density of sheet defects (i.e., a low density of misorientations and grain boundaries). Sintering of the crystal is performed, for example, by heating the crystallites on the surface of the liquid, by applying ultrasonic agitation, mechanical agitation, material deposition, or a combination thereof, as described with reference to FIG. 1.

In procedure 552 the sintered oriented crystalline sheet is removed from the container, for example by using a net, a track, or tweezers. After removal of the crystalline sheet from the container, the sheet can be used.

It will be appreciated by persons skilled in the art that the disclosed technique is not limited to what has been particularly shown and described hereinabove. Rather the scope of the disclosed technique is defined only by the claims, which follow.

1. Method for forming a crystalline sheet, comprising the procedures of:
introducing a plurality of crystallites in a first location of a liquid, wherein said liquid comprises chemical and physical properties with respect to said crystallites such that at least a portion of said crystallites are floating crystallites which float on the surface of said liquid, while preventing sintering of said floating crystallites in said first location;
arranging said floating crystallites in a uniformly oriented compact mosaic configuration while preventing sintering of said floating crystallites, said procedure of arranging comprising the sub-procedures of:
inducing movement of said floating crystallites from said first location to a second location of said liquid; and
allowing self-orientation of said floating crystallites in said second location until said floating crystallites are uniformly oriented in a compact mosaic configuration; and
forming a uniformly oriented crystalline sheet from said compact mosaic configuration.

2. The method according to claim 1, wherein said procedure of forming comprises sintering said floating crystallites while in said compact mosaic configuration.

3. The method according to claim 2, wherein said procedure of sintering comprises at least one procedure selected from the list consisting of: heating, depositing, applying ultrasound waves, applying a scanning energy beam, applying a laser beam, applying an electron beam, applying lighting to said floating crystallites, and using a hot filament.

4. The method according to claim 2, wherein said procedure of sintering comprises depositing, wherein said depositing fills in gaps between said floating crystallites.

5. The method according to claim 1, further comprising at least one procedure selected from the list consisting of: gluing said uniformly oriented crystalline sheet to a substrate, sintering said uniformly oriented crystalline sheet to a substrate, growing epitaxial layers on top of said uniformly oriented crystalline sheet, doping said uniformly oriented crystalline sheet, metallizing said uniformly oriented crystalline sheet, sectioning said uniformly oriented crystalline sheet, and performing micro-fabrication processes on said uniformly oriented crystalline sheet.

6. The method according to claim 1, further comprising the procedure of attaching the arranged crystallites in said compact mosaic configuration before said procedure of forming.

7. The method according to claim 5, wherein said procedure of attaching comprises at least one procedure selected from the list consisting of: sintering said arranged crystallites, gluing said arranged crystallites to a substrate, sintering said arranged crystallites to a substrate, growing epitaxial layers on top of said arranged crystallites, and doping said arranged crystallites.

8. The method according to claim 6, further comprising the procedure of maintaining said uniformly oriented compact mosaic configuration before said procedure of attaching.

9. The method according to claim 1, further comprising the procedure of filling at least one container with said liquid.

10. The method according to claim 9, wherein said first location and said second location are located in said at least one container.

11. The method according to claim 9, wherein said first location is located in one of said at least one container and said second location is location in another one of said at least one container.

12. The method according to claim 1, wherein said procedure of introducing comprises placing already grown crystallites on said first location.

13. The method according to claim 1, wherein said procedure of introducing comprises growing said crystallites in said first location.

14. The method according to claim 1, wherein said sub-procedure of inducing comprises at least one procedure selected from the list consisting of: applying a gravitational stream, thermo-capillarity, applying an electromagnetic field, mechanical waving, propelling, stirring, mixing, applying thermal convection, and pumping.

15. The method according to claim 1, wherein said sub-procedure of allowing comprises ultrasonically agitating said floating crystallites for assisting said floating crystallites in self-orientation, by applying ultrasound waves.

16. The method according to claim 1, wherein said sub-procedure of allowing comprises mechanically agitating said floating crystallites for assisting said floating crystallites in self-orientation, by applying mechanical vibrations to said liquid.

17. The method according to claim 1, wherein said sub-procedure of allowing comprises electromagnetically agitating said floating crystallites for assisting said floating crystallites in self-orientation, by inducing at least one of: a time varying magnetic field and a time varying electrical field.

18. The method according to claim 1, further comprising the procedure of inducing movement of said floating crystallites in said second location to another location before said procedure of forming.

19. The method according to claim 1, further comprising the procedures of:
pre-processing a portion of a track;
directing said pre-processed portion into said second location below the surface of said liquid;
collecting said floating crystallites on said pre-processed portion and removing said pre-processed portion from said liquid, wherein the uniform orientation of the collected crystallites is maintained; and
post-processing at least one of: said pre-processed portion and said collected crystallites.

20. The method according to claim 19, wherein said procedure of pre-processing comprises at least one procedure selected from the list consisting of: perforating said track, cleaning said track using wet chemicals, drying said track, applying an argon plasma on said track for physical cleaning, sputtering said track with a chemical element, sputtering said track with a molecule, altering the temperature of said track, and indenting said track at predetermined space intervals.

21. The method according to claim 19, wherein said procedure of post-processing comprises at least one procedure selected from the list consisting of: sintering said collected crystallites, gluing said collected crystallites to a substrate, bonding said collected crystallites, sintering said collected crystallites to a substrate, growing epitaxial layers on said collected crystallites, doping said collected crystallites, metallizing said collected crystallites, growing epitaxial films on said collected crystallites, growing hetero-epitaxial structures on said collected crystallites, depositing a row of conducting and dielectric thin films of different substances on said collected crystallites, gluing said crystalline sheet to a substrate, sintering said uniformly oriented crystalline sheet to a substrate, growing epitaxial layers on said uniformly oriented crystalline sheet, doping said uniformly oriented crystalline sheet, metallizing said uniformly oriented crystalline sheet, sectioning said uniformly oriented crystalline sheet, performing micro-fabrication processes on said uniformly oriented crystalline sheet, sectioning said pre-processed portion, and performing micro-fabrication processes on said pre-processed portion.

22. The method according to claim 1, wherein the temperature at said first location is lower than the temperature required for sintering said crystallites.

23. The method according to claim 1, wherein the rate at which said crystallites are introduced to said first location is such that only a single layer of said crystallites will be present on the surface of said liquid in said first location.

24. The method according to claim 1, wherein said crystallites comprise group-III metal nitride crystallites, said liquid comprises a group-III metal melt with chemical and physical properties with respect to said group-III metal nitride crystallites such that at least a portion of said group-III metal nitride crystallites float on the surface of said group-III metal melt.

25. The method according to claim 24, further comprising the procedures of:
filling at least one container with said group-III metal melt;
creating a sub-atmospheric pressure of nitrogen in said first location suitable for group-III metal nitride crystal growth;
heating said first location to a group-III metal nitride crystal growth temperature; and
directing a nitrogen plasma to said first location,
wherein said procedures of creating, heating and directing cause group-III metal nitride crystal growth.

26. Method for forming a crystalline sheet, comprising the procedures of:
introducing a plurality of crystallites into a liquid, wherein said liquid comprises chemical and physical properties with respect to said crystallites such that at least a portion of said crystallites are floating crystallites which float on the surface of said liquid, while preventing sintering of said floating crystallites in said liquid;
inducing self-orientation of said floating crystallites in said liquid until said floating crystallites are uniformly oriented in a compact mosaic configuration, while preventing sintering of said floating crystallites in said liquid; and
forming a uniformly oriented crystalline sheet from said compact mosaic configuration.

27. The method according to claim 26, wherein said procedure of introducing comprises maintaining temperature and pressure conditions, suitable for growing crystallites in said liquid, for a period of time sufficient for growing said crystallites from said liquid and insufficient for sintering said crystallites.

28. The method according to claim 26, further comprising the procedure of moving said floating crystallites in a closed loop after said procedure of introducing such that said crystallites leave the location of introducing and then subsequently return to said location before said procedure of inducing.

29. The method according to claim 28, wherein said closed loop comprises at least one selected from the list consisting of: a closed loop on the surface of said liquid, a closed loop below the surface of said liquid and a closed loop above the surface of said liquid.

30. Apparatus for forming a crystalline sheet, comprising:
a container, containing a liquid, wherein a plurality of crystallites are introduced into a first location of said container, and wherein at least a portion of said crystallites are floating crystallites that float on the surface of said liquid without sintering;
a flow unit for inducing a flow of said liquid which moves said floating crystallites from said first location to a second location of said container, wherein no sintering of said floating crystallites occurs; and
crystal self-orientation means for allowing self-orientation of said floating crystallites in said second location without sintering, until said floating crystallites are uniformly oriented in a compact mosaic configuration,
wherein a uniformly oriented crystalline sheet is formed from said compact mosaic configuration.

31. The apparatus according to claim 30, further comprising crystal sintering prevention means for preventing sintering of said floating crystallites.

32. The apparatus according to claim 31, wherein said crystal sintering prevention means comprise a temperature controller, for adjusting the temperature in said first location or in said second location to a temperature lower than the sintering temperature of said floating crystallites.

33. The apparatus according to claim 31, wherein said crystal sintering prevention means comprise a crystal introduction rate controller for controlling the rate at which said crystallites are introduced to said first location, such that only a single layer of said crystallites will be present on the surface of said liquid in said first location.

34. The apparatus according to claim 30, further comprising a sintering means for sintering said compact mosaic configuration, thereby forming a uniformly oriented crystalline sheet.

35. The apparatus according to claim 34, wherein said sintering means comprises at least one selected from the list consisting of: a heater, a scanning energy beam emitter, a laser beam emitter, an electron beam emitter, a lighting means, a hot filament, a material deposition means, and a sintering ultrasound unit.

36. The apparatus according to claim 34, wherein said sintering means is located adjacent to said second location.

37. The apparatus according to claim 30, further comprising a heater for inducing said flow in said liquid using thermal convection, said heater adjacent to said first location.

38. The apparatus according to claim 37, wherein the location of said heater is selected from the list consisting of: below said first location, above said first location, to the side of said first location, and inside said liquid in said first location.

39. The apparatus according to claim 30, wherein said flow unit comprises at least one selected from the list consisting of: a gravitational stream inducer for generating a stream in said liquid using gravity, a surface movement inducer for inducing thermo-capillary surface movement of said liquid by applying a temperature difference to said liquid surface, an electromagnetic field generator for generating a magnetic field and an electrical field in said liquid, a mechanical waving propelling means for generating a propulsion in said liquid, a stirrer for stirring said liquid, a mixer for mixing said liquid, a heater for generating thermal convection of said liquid, and a pump for pumping said liquid.

40. The apparatus according to claim 30, wherein said container comprises a predetermined shape for assisting in inducing said flow of said liquid.

41. The apparatus according to claim 40, wherein said container, from a top view, comprises a lobe at one end, a tapered section at another end and a broadened middle section.

42. The apparatus according to claim 40, wherein said container, from a top view, comprises a rectangular shape, having a tapered section at one end.

43. The apparatus according to claim 40, wherein said container, from a top view, comprises a lozenge-like shape.

44. The apparatus according to claim 40, wherein the depth of said container is substantially constant.

45. The apparatus according to claim 40, wherein said container comprises a curved floor defining a deeper section relative to the remainder of said container.

46. The apparatus according to claim 40, wherein said container, comprises a sloping floor such that said first location is deeper than said second location.

47. The apparatus according to claim 30, wherein said crystal self-orientation means comprise an ultrasound unit, coupled to said second location, for assisting said floating crystallites in self-orientation by applying ultrasound waves.

48. The apparatus according to claim 30, wherein said crystal self-orientation means comprises a vibrator, coupled to said second location, for assisting said floating crystallites in self-orientation by applying mechanical vibrations to said liquid.

49. The apparatus according to claim 30, wherein said crystal self-orientation means comprises an electromagnetic field generator, coupled with said second location, for assisting said floating crystallites in self-orientation by inducing at least one of: a time varying magnetic field and a time varying electrical field.

50. The apparatus according to claim 30, wherein said crystal self-orientation means comprises a guiding element at said second location of said container, for assisting said floating crystallites in self-orientating.

51. The apparatus according to claim 50, wherein said guiding element comprises a zigzagged boundary, wherein the zigzags of said zigzagged boundary are angled at a predetermined angle, wherein said predetermined angle is selected to best suit the geometric shape of said crystallites.

52. The apparatus according to claim 30, wherein said crystallites are introduced into said first location by growing said crystallites from said liquid.

53. The apparatus according to claim 30, wherein said crystallites are introduced into said first location by physically providing said crystallites into said first location.

54. The apparatus according to claim 30, further comprising a collecting means for collecting said floating crystallites, when said floating crystallites are uniformly oriented in said compact mosaic configuration.

55. The apparatus according to claim 54, wherein said collecting means comprise a track, and a plurality of rollers, coupled with said track, wherein said rollers are configured to direct said track to enter and exit said liquid.

56. The apparatus according to claim 55, wherein said track is configured to enter said second location, under the surface of said liquid, and exit said second location, such that said compact mosaic configuration is collected onto said track before sintering.

57. The apparatus according to claim 55, wherein said track is configured to enter said second location, under the surface of said liquid, and exit said second location, such that said uniformly oriented crystalline sheet is collected onto said track after sintering.

58. The apparatus according to claim 55, wherein said track is selected from the list consisting of: a conveyer belt, a substrate in the form of a conveyer belt, and a substrate placed upon a conveyer belt.

59. The apparatus according to claim 55, wherein said track comprises a material selected from the list consisting of: stainless steel, tantalum, molybdenum, steel, aluminum, copper alloys, paper, plastic, fabric, composite materials and graphite fabric.

60. The apparatus according to claim 55, further comprising a pre-processing unit, wherein said track is configured to pass through said pre-processing unit, before entering said liquid.

61. The apparatus according to claim 60, wherein said pre-processing unit comprises at least one selected from the list consisting of:
sputtering means for sputtering said track with a chemical element;
sputtering means for sputtering said track with a molecule;
temperature controller for altering the temperature of said track;
indenter for indenting said track at predetermined space intervals;
perforator for perforating said track;
cleaner for cleaning said track using wet chemicals;
dryer for drying said track; and
an argon plasma generator for applying an argon plasma on said track for physical cleaning.

62. The apparatus according to claim 55, further comprising a post-processing unit, wherein said track is configured to pass through said post-processing unit after exiting from said liquid.

63. The apparatus according to claim 55, wherein said post-processing unit comprises at least one selected from the list consisting of:
sputtering means for sputtering said track with a chemical element;
sputtering means for sputtering said track with a molecule;
sectioning means for sectioning said track; and
micro-fabrication means for performing micro-fabrication processes on said track.

64. The apparatus according to claim 56, wherein said post-processing unit comprises at least one selected from the list consisting of:
sintering means for sintering said compact mosaic configuration, thereby forming a uniformly oriented crystalline sheet;
sintering means for sintering said compact mosaic configuration to a substrate;
gluing means for gluing said compact mosaic configuration to a substrate;
crystal growth means for growing epitaxial layers on said compact mosaic configuration; and
depositor for depositing a row of conducting or dielectric thin films of different substances on said compact mosaic configuration.

65. The apparatus according to claim 57, wherein said post-processing unit comprises at least one selected from the list consisting of:
metallizer for metallizing said uniformly oriented crystalline sheet;
micro-fabrication means for performing micro-fabrication processes on said uniformly oriented crystalline sheet;
doping means for doping said uniformly oriented crystalline sheet; and
sectioning means for sectioning said uniformly oriented crystalline sheet.

66. The apparatus according to claim 30, wherein said first location and said second location coincide.

67. The apparatus according to claim 30, wherein said crystallites are induced to move in a closed loop, such that said crystallites leave said first location and return to said first location.

68. The apparatus according to claim 67, wherein said closed loop is selected from the list consisting of: a closed loop on the surface of said liquid, a closed loop below the surface of said liquid, and a closed loop above the surface of said liquid.

69. The apparatus according to claim 30, wherein said liquid is a group-III metal melt.

70. The apparatus according to claim 69, further comprising:
a nitrogen plasma generator, located above said first location, for generating a nitrogen plasma;
a pressure means for creating a sub-atmospheric pressure in said first location, suitable for group-III metal nitride crystal growth; and
a heater, located adjacent to said first location, for heating said first location to a group-III metal nitride crystal growth temperature,
wherein said sub-atmospheric pressure, said heated first location and said nitrogen plasma cause the growth of group-III metal nitride crystallites from said group-III metal melt.

71. The apparatus according to claim 70, wherein the location of said heater is selected from the list consisting of: below said first location, above said first location, to the side of said first location, and inside said group-III metal melt in said first location.

72. The apparatus according to claim 69, wherein said group-III metal melt is selected from the list consisting of: a gallium melt, an indium melt, and an aluminum melt.

73. The apparatus according to claim 30, further comprising at least one element for altering at least one condition in said apparatus, said condition selected from the list consisting of: the pressure inside said apparatus and the temperature inside said apparatus.

74. Apparatus for forming a crystalline sheet, comprising:
a first container, containing a liquid, wherein a plurality of crystallites are introduced into said first container, and wherein at least a portion of said crystallites are floating crystallites that float on the surface of said liquid without sintering;
a second container;
a movement inducing means for moving said floating crystallites from said first container to said second container, without sintering of said floating crystallites; and
crystal self-orientation means for allowing self-orientation of said floating crystallites in said second container without sintering, until said floating crystallites are uniformly oriented in a compact mosaic configuration,
wherein a uniformly oriented crystalline sheet is formed from said compact mosaic configuration.
